(19) United States
(12) Patent Application Publication
(10) Pub. No.: US 2026/0255840 A1
(43) Pub. Date: Aug. 27, 2026

(54) DISPLAY DEVICE AND ELECTRONIC DEVICE COMPRISING THE SAME

(71) Applicant: Samsung Display Co., Ltd., Yongin-si (KR)

(72) Inventor: Il Ha SONG, Yongin-si (KR)

(21) Appl. No.: 19/394,407

(22) Filed: Nov. 19, 2025

(30) Foreign Application Priority Data
Feb. 21, 2025 (KR) 10-2025-0022626

(51) Int. Cl. H10K 59/80

(52) U.S. Cl. CPC H10K 59/80515

(57) ABSTRACT

A display device and an electronic device including the display device are provided. The display device includes: a step portion defined by a plurality of side surfaces opposite to each other and a lower surface and an upper surface opposite to each other; a first electrode on the upper surface and the plurality of side surfaces of the step portion; a light emitting stack on the first electrode; and a second electrode on the light emitting stack, wherein a distance from a first point adjacent to the upper surface of the step portion on the side surface of the step portion to a side surface of the first electrode is different from a distance from a second point adjacent to the lower surface of the step portion on the side surface of the step portion to the side surface of the first electrode.

### CROSS-REFERENCE TO RELATED APPLICATION

The present application claims priority to and the benefit of Korean Patent Application No. 10-2025-0022626, filed on Feb. 21, 2025, in the Korean Intellectual Property Office, the entire content of which is incorporated herein by reference.

### BACKGROUND

### 1. Field

One or more embodiments of the present disclosure relate to a display device and an electronic device including the same.

### 2. Description of the Related Art

A head mounted display (HMD) is an image display device worn on a user's head in the form of glasses or a helmet, and is configured to present images at a short focal distance from the user's eyes (e.g., to present images at the close distance in front of the user's eyes). Head mounted displays may be used to implement virtual reality (VR) or augmented reality (AR) experiences.

A head mounted display magnifies and displays an image displayed by a small display device using a plurality of lenses. Therefore, a display device (e.g., a display panel) applied to the head mounted display may need to provide a high-resolution image, for example, images with a resolution of about 3000 pixels per inch (PPI) or more. To meet this requirement, an organic light emitting diode on silicon (OLEDoS), which is a small organic light emitting display device having a high resolution, may be employed. The OLEDoS refers to a device in which organic light emitting diodes (OLEDs) are formed on a semiconductor wafer substrate that includes complementary metal oxide semiconductors (CMOSs) circuitry.

### SUMMARY

One or more aspects of embodiments of the present disclosure are directed toward a display device capable of providing a high-resolution image.

One or more aspects of embodiments of the present disclosure are directed toward a head mounted display capable of providing a high-resolution image.

However, aspects of the present disclosure are not restricted to those set forth herein. The above and other aspects of the present disclosure will become more apparent to one of ordinary skill in the art to which the present disclosure pertains by referencing the detailed description of the present disclosure provided herein or by practice of the presented embodiments of the disclosure.

According to one or more embodiments of the present disclosure, a display device includes: a step portion defined by a plurality of side surfaces opposite to (e.g., facing) each other and a lower surface and an upper surface opposite to (e.g., facing) each other; a first electrode on (e.g., located on) the upper surface and the plurality of side surfaces of the step portion; a light emitting stack on (e.g., located on) the first electrode; and a second electrode on (e.g., located on) the light emitting stack, wherein a distance from a first point adjacent to the upper surface of the step portion on the side surface of the step portion to a side surface of the first electrode is different from a distance from a second point adjacent to the lower surface of the step portion on the side surface of the step portion to the side surface of the first electrode.

According to one or more embodiments of the present disclosure, a distance from the upper surface of the step portion to an upper surface of the first electrode may be smaller than a distance from the side surface of the step portion to the side surface of the first electrode.

According to one or more embodiments of the present disclosure, a first area and a plurality of second areas arranged at one side and the other side of the first area may be defined on the upper surface of the step portion. The first area may be located between the plurality of second areas, and in the first area, a distance from the upper surface of the step portion to an upper surface of the first electrode may be smaller than a distance from the upper surface of the step portion to an upper surface of the first electrode in the second areas.

According to one or more embodiments of the present disclosure, the light emitting stack may be in contact with the first electrode in at least a portion of the first area.

According to one or more embodiments of the present disclosure, an auxiliary electrode located between the step portion and the first electrode in the second area may be further included.

According to one or more embodiments of the present disclosure, the auxiliary electrode may include a same material as the first electrode.

According to one or more embodiments of the present disclosure, the auxiliary electrode may include an opening formed on the step portion, and the first electrode may be located in the opening.

According to one or more embodiments of the present disclosure, the opening may be formed in the first area.

According to one or more embodiments of the present disclosure, a plane including the lower surface of the step portion may form a first angle with the side surface of the step portion, the plane including the lower surface of the step portion may form a second angle with the side surface of the first electrode, and the first angle may be greater than the second angle.

According to one or more embodiments of the present disclosure, the first angle and the second angle may each be an acute angle.

According to one or more embodiments of the present disclosure, a central area and an outer area around (e.g., surrounding) the central area may be defined on a plane including the lower surface of the step portion, and a distance from the side surface of the step portion to the side surface of the first electrode may increase from the central area toward a direction in which the outer area is located.

According to one or more embodiments of the present disclosure, in the outer area, a distance from the plane including the lower surface of the step portion to an upper surface of the first electrode may be greater than a distance from the side surface of the step portion to the side surface of the first electrode.

According to one or more embodiments of the present disclosure, a distance from the upper surface of the step portion to the upper surface of the first electrode may be smaller than the distance from the plane including the lower surface of the step portion to the upper surface of the first electrode in the outer area.

According to one or more embodiments of the present disclosure, a first area and a second area may be defined on the upper surface of the step portion. On the upper surface of the step portion, a distance from the upper surface of the step portion to the upper surface of the first electrode may be smaller in the first area than in the second area, and the distance from the upper surface of the step portion to the upper surface of the first electrode in the second area may be substantially the same as the distance from the plane including the lower surface of the step portion to the upper surface of the first electrode in the outer area.

According to one or more embodiments of the present disclosure, the step portion may include a connection electrode, a reflective electrode on (e.g., located on) the connection electrode, and a step layer on (e.g., located on) the reflective electrode, and the first electrode may be electrically connected to the connection electrode on the side surface of the step portion.

According to one or more embodiments of the present disclosure, an electronic device includes:
a processor configured to provide an image signal;
a display module configured to receive the image signal provided from the processor and to display an image; and
a power module configured to supply power to the display module,
wherein the display module includes:
a step portion defined by a plurality of side surfaces opposite to (e.g., facing) each other and a lower surface and an upper surface opposite to (e.g., facing) each other;
a first electrode on (e.g., located on) the upper surface and the plurality of side surfaces of the step portion;
a light emitting stack on (e.g., located on) the first electrode; and
a second electrode on (e.g., located on) the light emitting stack,
wherein a distance from a first point adjacent to the upper surface of the step portion on the side surface of the step portion to a side surface of the first electrode is different from a distance from a second point adjacent to the lower surface of the step portion on the side surface of the step portion to the side surface of the first electrode.

According to one or more embodiments of the present disclosure, a distance from the upper surface of the step portion to an upper surface of the first electrode may be smaller than a distance from the side surface of the step portion to the side surface of the first electrode.

According to one or more embodiments of the present disclosure, an auxiliary electrode located between the step portion and the first electrode in the second area may be further included.

According to one or more embodiments of the present disclosure, the auxiliary electrode may include a same material as the first electrode.

According to one or more embodiments of the present disclosure, a plane including the lower surface of the step portion may form a first angle with the side surface of the step portion, the plane including the lower surface of the step portion may form a second angle with the side surface of the first electrode, and the first angle may be greater than the second angle.

A display device according to one or more embodiments of the present disclosure may reduce a disconnection probability of a first electrode arranged on a step portion by adjusting a taper angle formed between the side surface of the step portion and the lower surface thereof. For example, by enhancing the geometric relationship between the step portion and the first electrode—such as by ensuring that the angle between the side surface of the step portion and the lower surface is greater than the angle between the side surface of the first electrode and the lower surface—mechanical stress concentrations at the electrode interface may be mitigated. Furthermore, the inclusion of an auxiliary electrode between the step portion and the first electrode in certain regions may further enhance structural integrity and electrical continuity. The auxiliary electrode may serve as a buffer or bridge, compensating for variations in deposition thickness or topography, thereby reducing the likelihood of open circuits or performance degradation. As a result, the overall light-emitting efficiency and reliability of the display device may be improved, contributing to enhanced image quality and device longevity in high-resolution applications such as head mounted displays.

### BRIEF DESCRIPTION OF DRAWINGS

The accompanying drawings are included to provide a further understanding of the present disclosure and are incorporated in and constitute a part of the present disclosure. The drawings illustrate embodiments of the present disclosure and, together with the description, serve to explain principles of the present disclosure. The above and other aspects and features of the present disclosure will become more apparent and appreciated from the following descriptions of example embodiments thereof with reference to the accompanying drawings, in which:

FIG. 1 is an exploded perspective view illustrating a display device according to one or more embodiments of the present disclosure;

FIG. 2 is a block diagram illustrating the display device according to one or more embodiments of the present disclosure;

FIG. 3 is an equivalent circuit diagram of a first sub-pixel according to one or more embodiments of the present disclosure;

FIG. 4 is a layout diagram illustrating an example of a display panel according to one or more embodiments of the present disclosure;

FIG. 5 is a layout diagram illustrating an example of the display area of FIG. 4 according to one or more embodiments of the present disclosure;

FIG. 6 is a layout diagram illustrating another example of the display area of FIG. 4 according to one or more embodiments of the present disclosure;

FIG. 7 is a cross-sectional view illustrating an example of the display panel taken along the line I1-I1′ of FIG. 5 according to one or more embodiments of the present disclosure;

FIG. 8 is a cross-sectional view illustrating another example of the display panel taken along the line I1-I1′ of FIG. 5 according to one or more embodiments of the present disclosure;

FIG. 9 is a schematic block diagram illustrating components included in a display device according to one or more embodiments of the present disclosure;

FIG. 10-12 are each a schematic block diagram illustrating a light emitting stack according to one or more embodiments of the present disclosure;

FIG. 13 is a partially enlarged view illustrating the portion J of FIG. 8 according to one or more embodiments of the present disclosure;

FIGS. 14 and 15 are each a cross-sectional view for describing a shape of a deposit according to a shape of a step portion according to one or more embodiments of the present disclosure;

FIG. 16 is a partially enlarged view illustrating the portion K of FIG. 13 according to one or more embodiments of the present disclosure;

FIGS. 17 and 18 are each a schematic block diagram for describing a lateral leakage phenomenon;

FIG. 19 is a schematic block diagram for describing a method for preventing or reducing the lateral leakage phenomenon according to one or more embodiments of the present disclosure;

FIG. 20 is a cross-sectional view illustrating a display device according to a second embodiment of the present disclosure;

FIG. 21 is a partially enlarged view illustrating the portion L of FIG. 20 according to one or more embodiments of the present disclosure;

FIG. 22 is a cross-sectional view illustrating a modified example of FIG. 20 according to one or more embodiments of the present disclosure;

FIG. 23 is a partially enlarged view illustrating the portion M of FIG. 22 according to one or more embodiments of the present disclosure;

FIGS. 24 to 29 are cross-sectional views for describing a method of manufacturing a display device according to one or more embodiments of the present disclosure;

FIG. 30 is a perspective view illustrating a head mounted display according to one or more embodiments of the present disclosure;

FIG. 31 is an exploded perspective view illustrating an example of the head mounted display device of FIG. 30 according to one or more embodiments of the present disclosure;

FIG. 32 is a perspective view illustrating a head mounted display according to one or more embodiments of the present disclosure;

FIG. 33 is a block diagram of an electronic device according to one or more embodiments of the present disclosure; and

FIG. 34 is a schematic view illustrating electronic devices according to various embodiments of the present disclosure.

### DETAILED DESCRIPTION

The advantages and features of one or more embodiments disclosed herein, and methods of achieving them, will become apparent upon reference to the embodiments described in more detail with accompanying drawings. However, the present disclosure is not limited to the embodiments disclosed herein, but may be embodied in many different forms, and these embodiments are provided merely to make the disclosure complete and to fully inform one of ordinary skill in the art to which the present disclosure pertains, and the present disclosure is defined by the scope of the appended claims and equivalents thereof.

References to an element or layer as being “on” another element or layer include both (e.g., simultaneously) cases in which the element or layer is directly on top of the other element or layer, or one or more other elements or layers are interposed therebetween. Throughout this disclosure, like reference numerals may refer to like components. The shapes, sizes, proportions, angles, numbers, and/or the like disclosed in the drawings to illustrate embodiments are examples and are not intended to be limiting to those shown herein.

Although “first,” “second,” and/or the like are used to describe one or more suitable components, the components are not limited by these terms. Thus, a first component referred to herein may also be referred as a second component without departing the technical idea of the present disclosure.

Each of the features of the one or more suitable embodiments disclosed herein may be combined or combinable with each other, in part or in whole, and may be technically interlocked and operated in a variety of ways, and each embodiment may be practiced independently of or in conjunction with one another.

One or more example embodiments will be described in more detail with reference to the accompanying drawings. Configurations that function substantially the same between embodiments are given the same drawing designation, and repeated description may not be provided for conciseness.

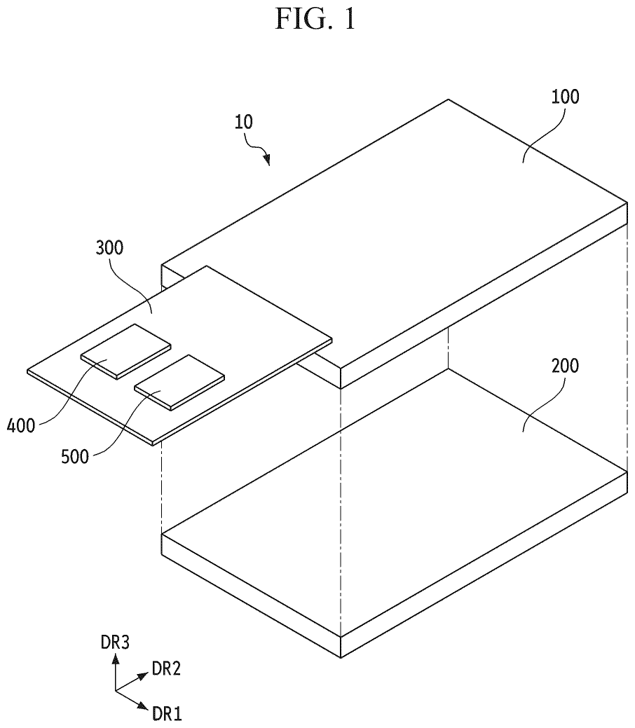

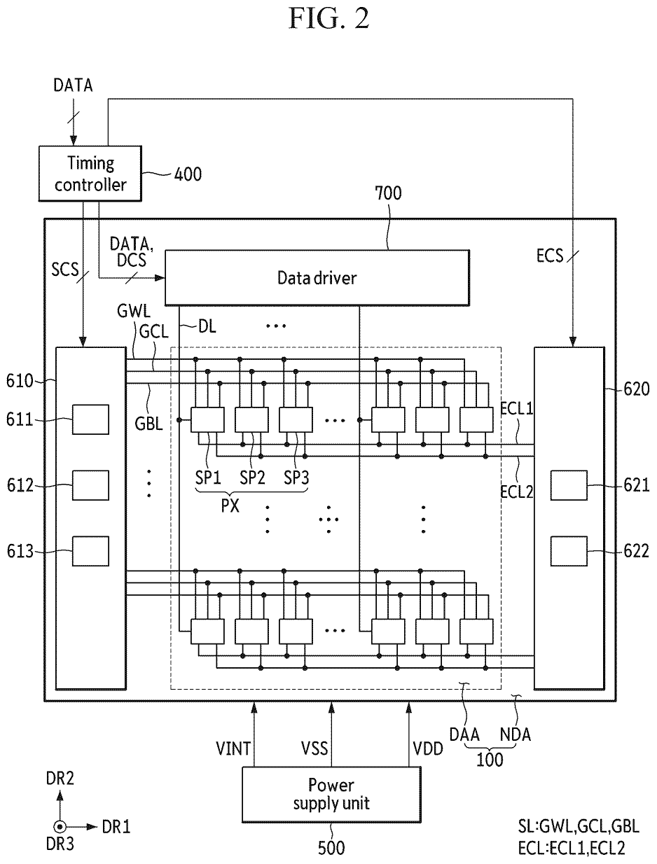

FIG. 1 is an exploded perspective view illustrating a display device according to one or more embodiments of the present disclosure. FIG. 2 is a block diagram illustrating the display device of FIG. 1 according to one or more embodiments of the present disclosure.

Referring to FIG. 1 and FIG. 2, a display device 10 according to one or more embodiments is a device that displays a moving image or a still image. The display device 10 according to one or more embodiments may be applied to portable electronic devices such as mobile phones, smartphones, tablet personal computers (PCs), mobile communication terminals, electronic notebooks, electronic books, portable multimedia players (PMPs), navigation devices, and/or ultra mobile PCs (UMPCs). For example, the display device 10 according to one or more embodiments may be applied as a display unit of televisions, laptop computers, monitors, billboards, or Internet of Things (IOTs) devices. In one or more embodiments, the display device 10 may be applied to smart watches, watch phones, or head mounted displays (HMDs) for implementing virtual reality and/or augmented reality.

The display device 10 according to one or more embodiments includes a display panel 100, a heat dissipation layer 200, a circuit board 300, a timing controller (e.g., timing control circuit) 400, and a power supply unit (e.g., power supply circuit) 500.

In one or more embodiments, the display panel 100 may have a shape similar to a rectangular shape in plan view. For example, the display panel 100 may have a shape similar to a rectangular shape, in plan view, having short sides in a first direction DR1 and long sides in a second direction DR2 crossing the first direction DR1. In the display panel 100, a corner where the short side in the first direction DR1 and the long side in the second direction DR2 meet may be rounded with a selected curvature or right-angled. A shape of the display panel 100 in plan view is not limited to the rectangular shape, for example, may be a shape similar to another polygonal shape, a circular shape, or an elliptical shape. A shape of the display device 10 in plan view may follow the shape of the display panel 100 in plan view, but embodiments of the present disclosure are not limited thereto.

In one or more embodiments, the display panel 100 includes a plurality of pixels PX, a plurality of scan lines SL, a plurality of emission control lines ECL, a plurality of data lines DL, a scan driver 610, an emission driver 620, and a data driver 700. The display panel 100 may be divided into a display area DAA that displays an image and a non-display area NDA that does not display an image, as illustrated in FIG. 2.

The plurality of pixels PX may be arranged in the display area DAA. The plurality of pixels PX may be arranged in a matrix form in the first direction DR1 and the second direction DR2. The plurality of scan lines SL and the plurality of emission control lines ECL may extend in the first direction DR1 and may be arranged in the second direction DR2. The plurality of data lines DL may extend in the second direction DR2 and may be arranged in the first direction DR1.

The plurality of scan lines SL may include a plurality of write scan lines GWL, a plurality of control scan lines GCL, and a plurality of bias scan lines GBL. The plurality of emission control lines ECL may include a plurality of first emission control lines ECL1 and a plurality of second emission control lines ECL2.

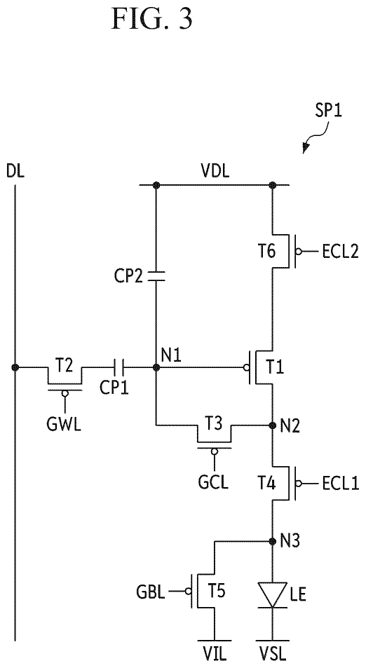

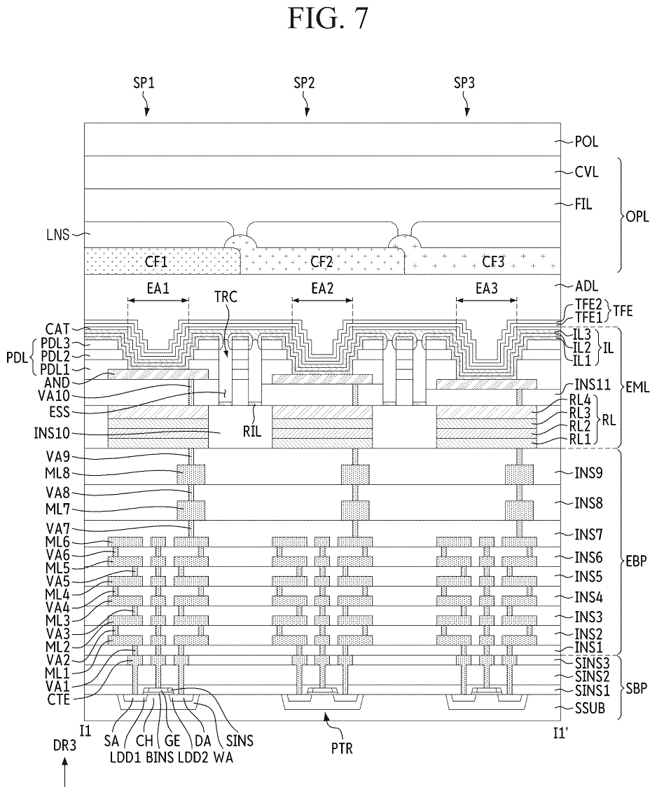

Each of the plurality of pixels PX may include a plurality of sub-pixels SP1, SP2, and SP3. The plurality of sub-pixels SP1, SP2, and SP3 may each include a plurality of pixel transistors as illustrated in FIG. 3, and the plurality of pixel transistors may each be formed by a semiconductor process and arranged on a semiconductor substrate SSUB (see FIG. 7). For example, in one or more embodiments, a plurality of pixel transistors of the data driver 700 may be formed as complementary metal oxide semiconductors (CMOSs), but embodiments of the present disclosure are not limited thereto.

Each of the plurality of sub-pixels SP1, SP2, and SP3 may be connected to a (e.g., one) write scan line GWL, a (e.g., one) control scan line GCL, a (e.g., one) bias scan line GBL, a (e.g., one) first emission control line ECL1, a (e.g., one) second emission control line ECL2, and a (e.g., one) data line DL. Each of the plurality of sub-pixels SP1, SP2, and SP3 may receive a data voltage of the data line DL according to a write scan signal of the write scan line GWL, and allow a light emitting element to emit light according to the data voltage.

In one or more embodiments, the scan driver 610, the emission driver 620, and the data driver 700 may each be arranged in the non-display area NDA.

The scan driver 610 includes a plurality of scan transistors, and the emission driver 620 includes a plurality of light emitting transistors. The plurality of scan transistors and the plurality of light emitting transistors may be formed by a semiconductor process and formed on the semiconductor substrate SSUB (see FIG. 7). For example, in one or more embodiments, the plurality of scan transistors and the plurality of light emitting transistors may be formed as CMOSs, but embodiments of the present disclosure are not limited thereto.

The scan driver 610 may include a write scan signal output unit 611, a control scan signal output unit 612, and a bias scan signal output unit 613. Each of the write scan signal output unit 611, the control scan signal output unit 612, and the bias scan signal output unit 613 may receive a scan timing control signal SCS from the timing controller 400. The write scan signal output unit 611 may generate write scan signals according to the scan timing control signal SCS of the timing controller 400 and sequentially output the write scan signals to the write scan lines GWL. The control scan signal output unit 612 may generate control scan signals according to the scan timing control signal SCS and sequentially output the control scan signals to the control scan lines GCL. The bias scan signal output unit 613 may generate bias scan signals according to the scan timing control signal SCS and sequentially output the bias scan signals to the bias scan lines GBL.

The emission driver 620 may include a first emission control driver 621 and a second emission control driver 622. Each of the first emission control driver 621 and the second emission control driver 622 may receive an emission timing control signal ECS from the timing controller 400. The first emission control driver 621 may generate first emission control signals according to the emission timing control signal ECS and sequentially output the first emission control signals to the first emission control lines ECL1. The second emission control driver 622 may generate second emission control signals according to the emission timing control signal ECS and sequentially output the second emission control signals to the second emission control lines ECL2.

The data driver 700 may include a plurality of data transistors, and the plurality of data transistors may be formed by a semiconductor process and formed on the semiconductor substrate SSUB (see FIG. 7). For example, in one or more embodiments, the plurality of data transistors may be formed as CMOSs, but embodiments of the present disclosure are not limited thereto.

The data driver 700 may receive digital video data DATA and a data timing control signal DCS from the timing controller 400. The data driver 700 converts the digital video data DATA into analog data voltages according to the data timing control signal DCS and outputs the analog data voltages to the data lines DL. In this regard, the sub-pixels SP1, SP2, and SP3 may be independently selected by the write scan signals of the scan driver 610, and the data voltages (e.g., analog data voltages) may be supplied to the selected sub-pixels SP1, SP2, and SP3.

The heat dissipation layer 200 may overlap the display panel 100 in a third direction DR3, which is a thickness direction of the display panel 100. The heat dissipation layer 200 may be arranged on a (e.g., one) surface, for example, a rear surface, of the display panel 100. The heat dissipation layer 200 serves to dissipate heat generated from the display panel 100. The heat dissipation layer 200 may include a layer made of graphite or a metal such as silver (Ag), copper (Cu), and/or aluminum (Al) having high thermal conductivity.

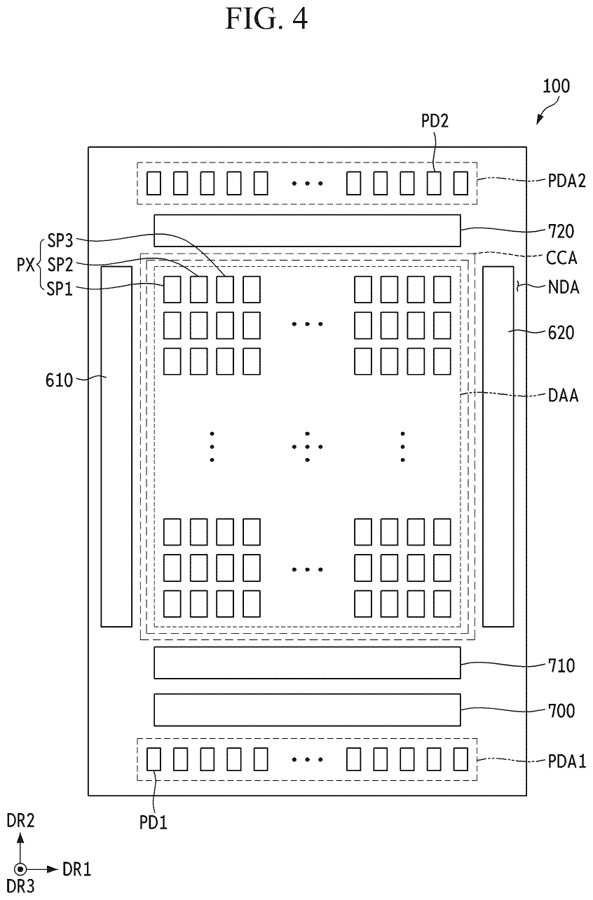

The circuit board 300 may be electrically connected to a plurality of first pads PD1 (see FIG. 4) of a first pad unit PDA1 (see FIG. 4) of the display panel 100 using a conductive adhesive member such as an anisotropic conductive film. In one or more embodiments, the circuit board 300 may be a flexible printed circuit board or a flexible film having a flexible material. It has been illustrated in FIG. 1 that the circuit board 300 is unbent, but the circuit board 300 may be bent. In this regard, one end of the circuit board 300 may be arranged on the rear surface of the display panel 100 and/or a rear surface of the heat dissipation layer 200. The other end of the circuit board 300 may be connected to the plurality of first pads PD1 (see FIG. 4) of the first pad unit PDA1 (see FIG. 4) of the display panel 100 using a conductive adhesive member. The one end of the circuit board 300 may be an end opposite to the other end of the circuit board 300.

The timing controller 400 may receive digital video data and timing signals from the outside. The timing controller 400 may generate the scan timing control signal SCS, the emission timing control signal ECS, and the data timing control signal DCS for controlling the display panel 100 according to the timing signals. The timing controller 400 may output the scan timing control signal SCS to the scan driver 610 and output the emission timing control signal ECS to the emission driver 620. The timing controller 400 may output the digital video data DATA and the data timing control signal DCS to the data driver 700.

The power supply unit 500 may generate a plurality of panel driving voltages according to an external source voltage. For example, in one or more embodiments, the power supply unit 500 may generate a first driving voltage VSS, a second driving voltage VDD, and a third driving voltage VINT and supply the first driving voltage VSS, the second driving voltage VDD, and the third driving voltage VINT to the display panel 100. The first driving voltage VSS, the second driving voltage VDD, and the third driving voltage VINT will be described in more detail later with reference to FIG. 3.

Each of the timing controller 400 and the power supply unit 500 may be formed as an integrated circuit (IC) and attached to a (e.g., one) surface of the circuit board 300. In this regard, the scan timing control signal SCS, the emission timing control signal ECS, the digital video data DATA, and the data timing control signal DCS of the timing controller 400 may be supplied to the display panel 100 through the circuit board 300. In addition, the first driving voltage VSS, the second driving voltage VDD, and the third driving voltage VINT of the power supply unit 500 may be supplied to the display panel 100 through the circuit board 300.

In one or more embodiments, each of the timing controller 400 and the power supply unit 500 may be arranged in the non-display area NDA of the display panel 100, similar to the scan driver 610, the emission driver 620, and the data driver 700. In these embodiments, the timing controller 400 may include a plurality of timing transistors, and the power supply unit 500 may include a plurality of power transistors. The plurality of timing transistors and the plurality of power transistors may be formed by a semiconductor process and formed on the semiconductor substrate SSUB (see FIG. 7). For example, in one or more embodiments, the plurality of timing transistors and the plurality of power transistors may be formed as CMOSs, but embodiments of the present disclosure are not limited thereto. In one or more embodiments, each of the timing controller 400 and the power supply unit 500 may be arranged between the data driver 700 and the first pad unit PDA1 (see FIG. 4).

FIG. 3 is an equivalent circuit diagram of a first sub-pixel according to one or more embodiments of the present disclosure.

Referring to FIG. 3, a first sub-pixel SP1 may be connected to a write scan line GWL, a control scan line GCL, a bias scan line GBL, a first emission control line ECL1, a second emission control line ECL2, and a data line DL. In addition, the first sub-pixel SP1 may be connected to a first driving voltage line VSL to which the first driving voltage VSS corresponding to a low potential voltage is applied, a second driving voltage line VDL to which the second driving voltage VDD corresponding to a high potential voltage is applied, and a third driving voltage line VIL to which the third driving voltage VINT corresponding to an initialization voltage is applied.

In one or more embodiments, the first sub-pixel SP1 includes a plurality of transistors T1 to T6, a light emitting element LE, a first capacitor CP1, and a second capacitor CP2.

The light emitting element LE emits light according to a driving current flowing through a channel of the first transistor T1. An amount (e.g., intensity) of light emitted from the light emitting element LE may be proportional to the driving. A first electrode of the light emitting element LE may be an anode electrode, and a second electrode of the light emitting element LE may be a cathode electrode. In one or more embodiments, the light emitting element LE may be an organic light emitting diode including a first electrode, a second electrode, and an organic light emitting layer arranged between the first electrode and the second electrode, but embodiments of the present disclosure are not limited thereto. For example, in one or more embodiments, the light emitting element LE may be an inorganic light emitting element including a first electrode, a second electrode, and an inorganic semiconductor arranged between the first electrode and the second electrode, and in these embodiments, the light emitting element LE may be a micro light emitting diode.

The first transistor T1 may be a driving transistor controlling a source-drain current (hereinafter referred to as a “driving current”) flowing between a source electrode and a drain electrode according to a voltage applied to a gate electrode thereof.

A second transistor T2 may be arranged between one electrode of the first capacitor CP1 and the data line DL. The second transistor T2 is turned on by a write scan signal of the write scan line GWL to connect the one electrode of the first capacitor CP1 to the data line DL. For this reason, a data voltage of the data line DL may be applied to the one electrode of the first capacitor CP1.

A third transistor T3 may be arranged between a first node N1 and a second node N2. The third transistor T3 is turned on by a control scan signal of the control scan line GCL to connect the first node N1 to the second node N2. For this reason, if (e.g., when) the gate electrode and the drain electrode of the first transistor T1 are connected to each other, the first transistor T1 may operate like a diode.

A fourth transistor T4 may be connected between the second node N2 and a third node N3. The fourth transistor T4 is turned on by a first emission control signal of the first emission control line ECL1 to connect the second node N2 to the third node N3. For this reason, the driving current of the first transistor T1 may be supplied to the light emitting element LE. A fifth transistor T5 may be arranged between the third node N3 and the third driving voltage line VIL. The fifth transistor T5 is turned on by a bias scan signal of the bias scan line GBL to connect the third node N3 to the third driving voltage line VIL. For this reason, the third driving voltage VINT of the third driving voltage line VIL may be applied to the first electrode of the light emitting element LE.

A sixth transistor T6 may be arranged between the source electrode of the first transistor T1 and the second driving voltage line VDL. The sixth transistor T6 is turned on by a second emission control signal of the second emission control line ECL2 to connect the source electrode of the first transistor T1 to the second driving voltage line VDL. For this reason, the second driving voltage VDD of the second driving voltage line VDL may be applied to the source electrode of the first transistor T1.

The first capacitor CP1 is formed between the first node N1 and a drain electrode of the second transistor T2. The second capacitor CP2 is formed between the gate electrode of the first transistor T1 and the second driving voltage line VDL.

Each of the first to sixth transistors T1 to T6 may be a metal oxide semiconductor field effect transistor (MOSFET). For example, in one or more embodiments, each of the first to sixth transistors T1 to T6 may be a P-type (kind) MOSFET, but embodiments of the present disclosure are not limited thereto. In one or more embodiments, each of the first to sixth transistors T1 to T6 may be an N-type (kind) MOSFET. In one or more embodiments, some of the first to sixth transistors T1 to T6 may be P-type (kind) MOSFETs, and the others of the first to sixth transistors T1 to T6 may be N-type (kind) MOSFETs.

It has been illustrated in FIG. 3 that the first sub-pixel SP1 includes six transistors T1 to T6 and two capacitors CP1 and CP2, but it is to be noted that an equivalent circuit diagram of the first sub-pixel SP1 is not limited to that illustrated in FIG. 3. For example, the numbers of transistors and capacitors of the first sub-pixel SP1 are not limited to those illustrated in FIG. 3.

In addition, an equivalent circuit diagram of a second sub-pixel SP2 and an equivalent circuit diagram of a third sub-pixel SP3 may each be substantially the same as the equivalent circuit diagram of the first sub-pixel SP1 described with reference to FIG. 3. Therefore, a description of the equivalent circuit diagram of the second sub-pixel SP2 and the equivalent circuit diagram of the third sub-pixel SP3 is not provided in the present disclosure.

FIG. 4 is a layout diagram illustrating an example of a display panel according to one or more embodiments of the present disclosure.

Referring to FIG. 4, the display area DAA of the display panel 100 according to one or more embodiments includes a plurality of pixels PX arranged in a matrix form. The non-display area NDA of the display panel 100 according to one or more embodiments includes a scan driver 610, an emission driver 620, a data driver 700, a first distribution circuit 710, a second distribution circuit 720, a first pad unit PDA1, and a second pad unit PDA2.

The scan driver 610 may be arranged on a first side of the display area DAA, and the emission driver 620 may be arranged on a second side of the display area DAA. For example, in one or more embodiments, the scan driver 610 may be arranged on one side of the display area DAA in the first direction DR1, and the emission driver 620 may be arranged on the other side of the display area DAA in the first direction DR1. However, embodiments of the present disclosure are not limited thereto, for example, in one or more embodiments, the scan drivers 610 and the emission drivers 620 may be arranged on both (e.g., simultaneously) the first and second sides of the display area DAA.

The first pad unit PDA1 may include a plurality of first pads PD1 connected to pads or bumps of the circuit board 300 through a conductive adhesive member. The first pad unit PDA1 may be arranged on a third side of the display area DAA. For example, in one or more embodiments, the first pad unit PDA1 may be arranged on one side of the display area DAA in the second direction DR2. The first pad unit PDA1 may be arranged outside the data driver 700 in the second direction DR2. For example, the first pad portion PDA1 may be arranged closer to an edge of the display panel 100 than the data driver 700 is to the edge.

The second pad unit PDA2 may include a plurality of second pads PD2 corresponding to inspection pads that inspect whether or not the display panel 100 operates normally. The plurality of second pads PD2 may be connected to a jig or a probe pin or connected to a circuit board for inspection in an inspection process. The circuit board for inspection may be a printed circuit board made of a rigid material or a flexible printed circuit board made of a flexible material.

The second pad unit PDA2 may be arranged on a fourth side of the display area DAA. For example, in one or more embodiments, the second pad unit PDA2 may be arranged on the other side of the display area DAA in the second direction DR2. The second pad unit PDA2 may be arranged outside the second distribution circuit 720 in the second direction DR2. For example, the second pad portion PDA2 may be arranged closer to an edge of the display panel 100 than the second distribution circuit 720 is to the edge.

The first distribution circuit 710 distributes data voltages applied through the first pad unit PDA1 to the plurality of data lines DL. For example, the first distribution circuit 710 may distribute data voltages applied through one first pad PD1 of the first pad unit PDA1 to P data lines DL (P is a positive integer of 2 or more), and for this reason, the number of first pads PD1 may be reduced. The first distribution circuit 710 may be arranged on the third side of the display area DAA of the display panel 100. For example, the first distribution circuit 710 may be arranged on one side of the display area DAA in the second direction DR2.

The second distribution circuit 720 distributes signals applied through the second pad unit PDA2 to the scan driver 610, the emission driver 620, and the data lines DL. The second pad unit PDA2 and the second distribution circuit 720 may be components for inspecting an operation of each of the pixels PX of the display area DAA. The second distribution circuit 720 may be arranged on the fourth side of the display area DAA of the display panel 100. For example, the second distribution circuit 720 may be arranged on the other side of the display area DAA in the second direction DR2. In the context of the present disclosure and unless defined otherwise, “one side of the display area DAA in the second direction DR2” refers to a specific side of the display area along the direction labeled as DR2. For instance, if DR2 represents a vertical direction, this may indicate the bottom side of the display area. Conversely, “the other side of the display area DAA in the second direction DR2” refers to the opposite side of the display area along the same direction DR2, which, continuing the previous example, may indicate the top side of the display area. These phrases are used to describe the positioning of components, such as distribution circuits, on opposite sides of the display area along the specified direction DR2.

A cathode connection portion CCA may be an area where a second electrode CAT (see FIG. 7) of a display element layer EML (see FIG. 7) is connected to the first driving voltage line VSL of the non-display area NDA. The cathode connection portion CCA may be arranged outside at least one side of the display area DAA. For example, in one or more embodiments, the cathode connection portion CCA may be arranged outside at least one side selected from the left side, the right side, the upper side, and the lower side of the display area DAA. In one or more embodiments, the cathode connection portion CCA may surround (e.g., be around) the display area DAA as illustrated in FIG. 4 in order to minimize or reduce a deviation of the first driving voltage VSS due to a voltage drop (IR drop) or voltage rising (IR rising) of the second electrode CAT in the display area DAA.

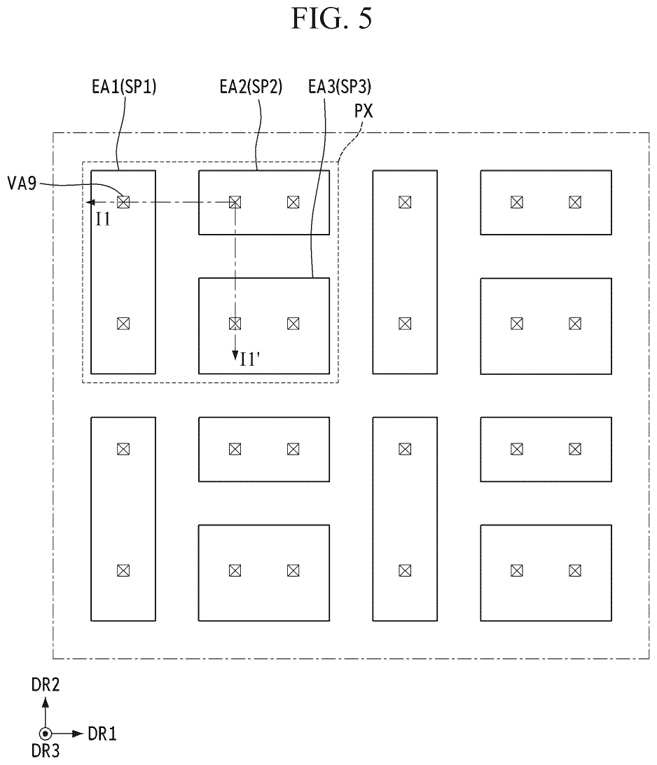

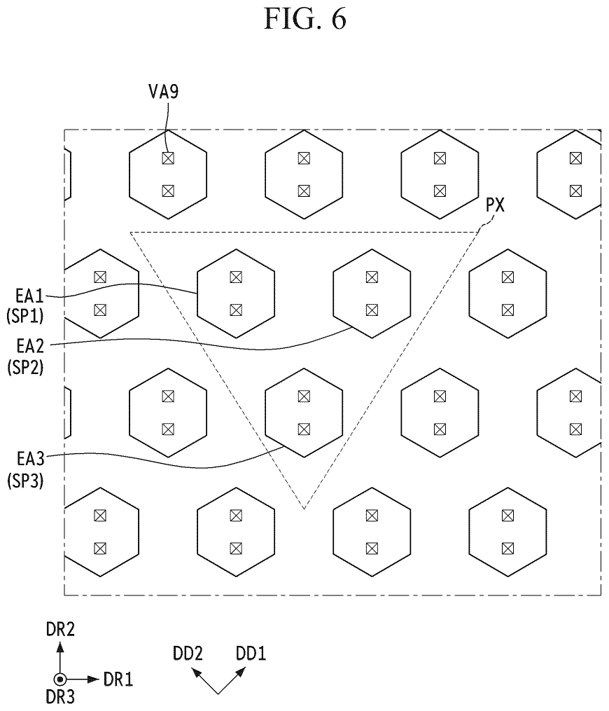

FIG. 5 is a layout diagram illustrating an example of the display area of FIG. 4 according to one or more embodiments of the present disclosure. FIG. 6 is a layout diagram illustrating another example of the display area of FIG. 4 according to one or more embodiments of the present disclosure.

Referring to FIGS. 5 and 6, each of the plurality of pixels PX includes a first emission area EA1 that is an emission area of the first sub-pixel SP1, a second emission area EA2 that is an emission area of the second sub-pixel SP2, and a third emission area EA3 that is an emission area of the third sub-pixel SP3. Each of the emission areas may have vias, for example, via VA9, which will be described in more detail later with reference to FIG. 7.

Each of the first emission area EA1, the second emission area EA2, and the third emission area EA3 may have a rectangular shape or a hexagonal shape in plan view, as illustrated in FIGS. 5 and 6, but embodiments of the present disclosure are not limited thereto. For example, each of the first emission area EA1, the second emission area EA2, and the third emission area EA3 may have a polygonal shape other than the rectangular shape or the hexagonal shape, a circular shape, an elliptical shape, or an irregular shape in plan view.

As illustrated in FIG. 5, in each of the plurality of pixels PX, the first emission area EA1 and the second emission area EA2 may neighbor to each other in the first direction DR1. In addition, the first emission area EA1 and the third emission area EA3 may neighbor to each other in the first direction DR1. In addition, the second emission area EA3 and the third emission area EA3 may neighbor to each other in the second direction DR2. An area of the first emission area EA1, an area of the second emission area EA2, and an area of the third emission area EA3 may be different from each other.

In one or more embodiments, as illustrated in FIG. 6, each of the emission areas EA1, EA2, EA3 may have a hexagonal planar shape. In these embodiments, the first emission area EA1 and the second emission area EA2 may be neighboring in the first direction DR1. The first light-emitting area EA1 and the third light-emitting area EA3 may be neighboring in a first diagonal direction DD1, and the second light-emitting area EA2 and the third light-emitting area EA3 may be neighboring in a second diagonal direction DD2. The first diagonal direction DD1 may be a direction between the first direction DR1 and the second direction DR2, and may refer to a direction inclined at a set or predetermined angle relative to the first direction DR1 and the second direction DR2. In one or more embodiments, said set or predetermined angle may be 45 degrees. The second diagonal direction DD2 may be a direction that intersects the first diagonal direction DD1. The second diagonal direction DD2 may be a direction orthogonal to the first diagonal direction DD1, but embodiments of the present disclosure are not limited thereto.

In one or more embodiments, the first sub-pixel SP1 may be to emit first light, the second sub-pixel SP2 may be to emit second light, and the third sub-pixel SP3 may be to emit third light. Here, the first light may be light of a blue wavelength band, the second light may be light of a green wavelength band, and the third light may be light of a red wavelength band. For example, the blue wavelength band may indicate that a main peak wavelength of the light is included in a wavelength band of approximately (about) 370 nanometers (nm) to (about) 460 nm, the green wavelength band may indicate that a main peak wavelength of the light is included in a wavelength band of approximately (about) 480 nm to (about) 560 nm, and the red wavelength band may indicate that a main peak wavelength of the light is included in a wavelength band of approximately (about) 600 nm to (about) 750 nm.

Each of the plurality of pixels PX may include three emission areas EA1, EA2, and EA3 as illustrated in FIG. 5 and FIG. 6. However, in one or more embodiments, a fourth emission area may be further included in a pixel PX and may be to emit a same second light as the second emission area EA2, but embodiments of the present disclosure are not limited thereto.

The emission areas of the plurality of pixels PX may be arranged in a stripe structure in which the emission areas are arranged in the first direction DR1, a PenTile® structure in which the emission areas EA1, EA2, EA3, and the fourth emission area have an arrangement of a rhombus shape, or a hexagonal structure in which the emission areas have an arrangement of a hexagonal shape. PenTile® is a duly registered trademark of Samsung Display Co., Ltd.

FIG. 7 is a cross-sectional view illustrating an example of the display panel taken along the line I1-I1′ of FIG. 5 according to one or more embodiments of the present disclosure.

Referring to FIG. 7, the display panel 100 may include a semiconductor backplane SBP, a light emitting element backplane EBP, a display element layer EML, an encapsulation layer TFE, an optical layer OPL, and a polarizing plate POL.

The semiconductor backplane SBP may include a semiconductor substrate SSUB including a plurality of pixel transistors PTR, a plurality of semiconductor insulating films covering the plurality of pixel transistors PTR, and a plurality of contact terminals CTE electrically connected to the plurality of pixel transistors PTR, respectively. The plurality of pixel transistors PTR may include (e.g., be) be the first to sixth transistors T1 to T6 described with reference to FIG. 3.

The semiconductor substrate SSUB may be a silicon substrate, a germanium substrate, or a silicon-germanium substrate. The semiconductor substrate SSUB may be a substrate doped with first-type (kind) impurities. A plurality of well regions WA may be arranged in an upper surface of the semiconductor substrate SSUB. The plurality of well regions WA may be regions doped with second-type (kind) impurities. The second-type (kind) impurities may be different from the first-type (kind) impurities described above. For example, in one or more embodiments, if (e.g., when) the first-type (kind) impurities are p-type (kind) impurities, the second-type (kind) impurities may be n-type (kind) impurities. In one or more embodiments, if (e.g., when) the first-type (kind) impurities are n-type (kind) impurities, the second-type (kind) impurities may be p-type (kind) impurities.

Each of the plurality of well regions WA may include a source region SA corresponding to a source electrode of the pixel transistor PTR, a drain region DA corresponding to a drain electrode of the pixel transistor PTR, and a channel region CH arranged between the source region SA and the drain region DA.

A bottom insulating film BINS may be arranged between a gate electrode GE and the well region WA. Side surface insulating films SINS may be arranged on side surfaces of the gate electrode GE. The side surface insulating films SINS may be arranged on the bottom insulating film BINS.

Each of the source region SA and the drain region DA may be a region doped with the first-type (kind) impurities. The gate electrode GE of the pixel transistor PTR may overlap the well region WA in the third direction DR3, which is a thickness direction of the semiconductor substrate SSUB. The channel region CH may overlap the gate electrode GE in the third direction DR3. The source region SA may be arranged on one side of the gate electrode GE, and the drain region SA may be arranged on the other side of the gate electrode GE.

Each of the plurality of well regions WA further includes a first low-concentration impurity region LDD1 arranged between the channel region CH and the source region SA and a second low-concentration impurity region LDD2 arranged between the channel region CH and the drain region DA. The first low-concentration impurity region LDD1 may be a region having a lower impurity concentration than the source region SA due to the bottom insulating film BINS. The second low-concentration impurity region LDD2 may be a region having a lower impurity concentration than the drain region DA due to the bottom insulating film BINS. A distance between the source region SA and the drain region DA may increase by the first low-concentration impurity region LDD1 and the second low-concentration impurity region LDD2, and for this reason, a length of the channel region CH of each of the pixel transistors PTR may increase.

A first semiconductor insulating film SINS1 may be arranged on the semiconductor substrate SSUB. A second semiconductor insulating film SINS2 may be arranged on the first semiconductor insulating film SINS1.

The plurality of contact terminals CTE may be arranged on the second semiconductor insulating film SINS2. Each of the plurality of contact terminals CTE may be connected to a corresponding one of the gate electrode GE, the source region SA, and the drain region DA of each of the pixel transistors PTR through a hole penetrating through the first semiconductor insulating film SINS1 and the second semiconductor insulating film SINS2. Each of the plurality of contact terminals CTE may be made of any one selected from among copper (Cu), aluminum (Al), tungsten (W), molybdenum (Mo), chromium (Cr), gold (Au), titanium (Ti), nickel (Ni), and neodymium (Nd), or an alloy thereof or a compound thereof.

A third semiconductor insulating film SINS3 may be arranged on side surfaces of each of the plurality of contact terminals CTE. An upper surface of each of the plurality of contact terminals CTE may be exposed without being covered by the third semiconductor insulating film SINS3.

Each of the first semiconductor insulating film SINS1, the second semiconductor insulating film SINS2, and the third semiconductor insulating film SINS3 may be independently formed as a silicon carbonitride (SiCN) film or a silicon oxide (SiOₓ)-based inorganic film, but embodiments of the present disclosure are not limited thereto.

In one or more embodiments, the semiconductor substrate SSUB may be replaced with a glass substrate or a polymer resin substrate such as a polyimide substrate. In these embodiments, thin film transistors may be arranged on the glass substrate or the polymer resin substrate. The glass substrate may be a rigid substrate that is not bent, and the polymer resin substrate may be a flexible substrate that may be bent or curved.

The display element layer EML and the light emitting element backplane EBP may include a plurality of conductive layers ML1 to ML8, a plurality of vias VA1 to VA9, and a plurality of insulating films INS1 to INS11. In addition, the light emitting element backplane EBP includes a plurality of insulating films INS1 to INS9 arranged between first to eighth conductive layers ML1 to ML8.

First to eighth insulating films INS1 to INS8 serve to insulate the first to eighth conductive layers ML1 to ML8 from one another. The first to eighth conductive layers ML1 to ML8 serve to implement a circuit of the first sub-pixel SP1 illustrated in FIG. 3 by connecting the plurality of contact terminals CTE exposed from the semiconductor backplane SBP to each other.

For example, in one or more embodiments, the first to sixth transistors T1 to T6 are merely formed in the semiconductor backplane SBP, and the connection between the first to sixth transistors T1 to T6 and the formation of the first capacitor CP1 and the second capacitor CP2 are performed through the first to eighth conductive layers ML1 to ML8. In addition, the connection between a drain region corresponding to the drain electrode of the fourth transistor T4, a source region corresponding to the source electrode of the fifth transistor T5, and a first electrode AND of the light emitting element LE is also performed through the first to eighth conductive layers ML1 to ML8.

The first to eighth conductive layers ML1 to ML8 and first to eighth vias VA1 to VA8 may be made of substantially a same material. Each of the first to eighth conductive layers ML1 to ML8 and the first to eighth vias VA1 to VA8 may be made of any one selected from among copper (Cu), aluminum (Al), tungsten (W), molybdenum (Mo), chromium (Cr), gold (Au), titanium (Ti), nickel (Ni), and neodymium (Nd), or an alloy thereof or a compound thereof. The first to eighth vias VA1 to VA8 may be made of substantially the same material. In one or more embodiments, the first to eighth insulating films INS1 to INS8 may each be formed as a silicon oxide (SiOₓ)-based inorganic film, but embodiments of the present disclosure are not limited thereto.

The ninth insulating film INS9 may be arranged on the eighth insulating film INS8 and the eighth conductive layer ML8. In one or more embodiments, the ninth insulating film INS9 may be formed as a silicon oxide (SiOₓ)-based inorganic film, but embodiments of the present disclosure are not limited thereto.

Each of ninth vias VA9 may penetrate through the ninth insulating film INS9 to be connected to the exposed eighth conductive layer ML8. Each of the ninth vias VA9 may be made of any one selected from among copper (Cu), aluminum (Al), tungsten (W), molybdenum (Mo), chromium (Cr), gold (Au), titanium (Ti), nickel (Ni), and neodymium (Nd), or an alloy thereof or a compound thereof.

The display element layer EML may be arranged on the light emitting element backplane EBP. The display element layer EML may include tenth and eleventh insulating films INS10 and INS11, a reflective electrode RL, first electrodes AND, a light emitting stack IL, a second electrode CAT, a pixel defining film PDL, and a plurality of trenches TRC.

The reflective electrode RL may be arranged on the ninth insulating film INS9. The reflective electrode RL may include one or more reflective electrodes selected from among reflective electrodes RL1, RL2, RL3, and RL4. For example, in one or more embodiments, the reflective electrode RL may include first to fourth reflective electrodes RL1, RL2, RL3, and RL4 as illustrated in FIG. 7.

The first reflective electrodes RL1 may be arranged on the ninth insulating film INS9 and be connected to the ninth via VA9. Each of the second reflective electrodes RL2 may be arranged on the first reflective electrode RL1 corresponding thereto. Each of the third reflective electrodes RL3 may be arranged on the second reflective electrode RL2 corresponding thereto. Each of the fourth reflective electrodes RL4 may be arranged on the third reflective electrode RL3 corresponding thereto.

Because the second reflective electrodes RL2 are electrodes substantially reflecting light from the light emitting elements LE, a thickness of the second reflective electrode RL2 may be greater than a thickness of the first reflective electrode RL1, a thickness of the third reflective electrode RL3, and a thickness of the fourth reflective electrode RL4.

Each of the first reflective electrodes RL1 may be made of any one selected from among copper (Cu), aluminum (Al), tungsten (W), molybdenum (Mo), chromium (Cr), gold (Au), titanium (Ti), nickel (Ni), and neodymium (Nd), or an alloy thereof or a compound thereof. For example, in one or more embodiments, each of the first reflective electrodes RL1 may include titanium nitride (TiN), each of the second reflective electrodes RL2 may include aluminum (Al), each of the third reflective electrodes RL3 may include titanium nitride (TiN), and each of the fourth reflective electrodes RL4 may include titanium (Ti).

The tenth insulating film INS10 may be arranged on the ninth insulating film INS9. The tenth insulating film INS10 may be arranged between the reflective electrodes RL neighboring to each other. The tenth insulating film INS10 may be a film for planarizing a step caused by the reflective electrode RL. The eleventh insulating film INS11 may be arranged on the tenth insulating film INS10 and the reflective electrode RL.

In one or more embodiments, the tenth insulating film INS10 and the eleventh insulating film INS11 may each be formed as a silicon oxide (SiOₓ)-based inorganic film, but embodiments of the present disclosure are not limited thereto.

The eleventh insulating film INS11 may be an optical auxiliary layer for adjusting a resonance distance of light emitted from the light emitting stack IL in at least one of the first sub-pixel SP1, the second sub-pixel SP2, or the third sub-pixel SP3. The eleventh insulating film INS11 may have different thicknesses in the first sub-pixel SP1, the second sub-pixel SP2, and the third sub-pixel SP3. For example, in order to adjust a distance from the reflective electrode RL to the second electrode CAT according to a main wavelength of light emitted from each of the first sub-pixel SP1, the second sub-pixel SP2, and third the sub-pixel SP3, the thickness of the eleventh insulating film INS11 may be set in each of the first sub-pixel SP1, the second sub-pixel SP2, and the third sub-pixel SP3.

For example, as illustrated in FIG. 7, a thickness of the eleventh insulating film INS11 in the first sub-pixel SP1 may be greater than a thickness of the eleventh insulating film INS11 in the second sub-pixel SP2, and the thickness of the eleventh insulating film INS11 in the second sub-pixel SP2 may be greater than a thickness of the eleventh insulating film INS11 in the third sub-pixel SP3. In this regard, a distance between the first electrode AND and the reflective electrode RL in the first sub-pixel SP1 may be greater than a distance between the first electrode AND and the reflective electrode RL in the second sub-pixel SP2. In addition, the distance between the first electrode AND and the reflective electrode RL in the second sub-pixel SP2 may be greater than a distance between the first electrode AND and the reflective electrode RL in the third sub-pixel SP3.

Each of tenth vias VA10 may penetrate through the eleventh insulating film INS11 to be connected to the exposed corresponding fourth reflective electrode RL4. Each of the tenth vias VA10 may be made of any one selected from among copper (Cu), aluminum (Al), tungsten (W), molybdenum (Mo), chromium (Cr), gold (Au), titanium (Ti), nickel (Ni), and neodymium (Nd), or an alloy thereof or a compound thereof. A thickness of the tenth via VA10 in the first sub-pixel SP1 may be greater than a thickness of the tenth via VA10 in the second sub-pixel SP2, and the thickness of the tenth via VA10 in the second sub-pixel SP2 may be greater than a thickness of the tenth via VA10 in the third sub-pixel SP3.

The first electrode AND of each of the light emitting elements LE may be arranged on the eleventh insulating film INS11 and be connected to the tenth via VA10. The first electrode AND of each of the light emitting elements LE may be connected to the drain region DA or the source region SA of the pixel transistor PTR through the tenth via VA10, the reflective electrode RL, the first to ninth vias VA1 to VA9, the first to eighth conductive layers ML1 to ML8, and the contact terminal CTE. The first electrode AND of each of the light emitting elements LE may be made of any one selected from among copper (Cu), aluminum (Al), tungsten (W), molybdenum (Mo), chromium (Cr), gold (Au), titanium (Ti), nickel (Ni), and neodymium (Nd), or an alloy thereof or a compound thereof. For example, in one or more embodiments, the first electrode AND of each of the light emitting elements LE may be made of titanium nitride (TiN).

The pixel defining film PDL may be arranged on a partial area of the first electrode AND of each of the light emitting elements LE. The pixel defining film PDL may cover an edge of the first electrode AND of each of the light emitting elements LE. The pixel defining film PDL may partition the first emission areas EA1, the second emission areas EA2, and the third emission areas EA3. Each of the first emission area EA1, the second emission area EA2, and the third emission area EA3 may be an area where the light emitting element LE including the first electrode AND, the light emitting stack IL, and the second electrode CAT is arranged.

The first emission area EA1 may be defined as an area where the first electrode AND, the light emitting stack IL, and the second electrode CAT are sequentially stacked in the first sub-pixel SP1 to emit light. The second emission area EA2 may be defined as an area where the first electrode AND, the light emitting stack IL, and the second electrode CAT are sequentially stacked in the second sub-pixel SP2 to emit light. The third emission area EA3 may be defined as an area where the first electrode AND, the light emitting stack IL, and the second electrode CAT are sequentially stacked in the third sub-pixel SP3 to emit light.

The pixel defining film PDL may include first to third pixel defining films PDL1, PDL2, and PDL3. The first pixel defining film PDL1 may be arranged on the edge of the first electrode AND of each of the light emitting elements LE, the second pixel defining film PDL2 may be arranged on the first pixel defining film PDL1, and the third pixel defining film PDL3 may be arranged on the second pixel defining film PDL2. In one or more embodiments, the first pixel defining film PDL1, the second pixel defining film PDL2, and the third pixel defining film PDL3 may each be formed as a silicon oxide (SiOₓ)-based inorganic film. In one or more embodiments, the first pixel defining film PDL1 and the third pixel defining film PDL3 may each be formed as a silicon nitride (SiNₓ)-based inorganic film, whereas the second pixel defining film PDL2 may be formed as a silicon oxide (SiOₓ)-based inorganic film. Each of a thickness of the first pixel defining film PDL1, a thickness of the second pixel defining film PDL2, and a thickness of the third pixel defining film PDL3 may be approximately 50 nm.

In order to prevent or reduce a first encapsulation inorganic film TFE1 from being disconnected due to step coverage, the first pixel defining film PDL1, the second pixel defining film PDL2, and the third pixel defining film PDL3 may have a cross-sectional structure with a step having a staircase shape. The step coverage refers to a ratio of a degree at which a thin film is coated on an inclined portion to a degree at which a thin film is coated on a flat portion. The lower the step coverage, the more likely it is that the thin film will be disconnected at the inclined portion.

Each of the plurality of trenches TRC may penetrate through the first pixel defining film PDL1, the second pixel defining film PDL2, and the third pixel defining film PDL3. In one or more embodiments, in each of the plurality of trenches TRC, the eleventh insulating film INS11 may have a shape in which at least a portion thereof trenches.

At least one trench TRC may be arranged between the sub-pixels SP1, SP2, and SP3 neighboring to each other. It has been illustrated in FIG. 7 that two trenches TRC are arranged between the sub-pixels SP1, SP2, and SP3 neighboring to each other, but embodiments of the present disclosure are not limited thereto.

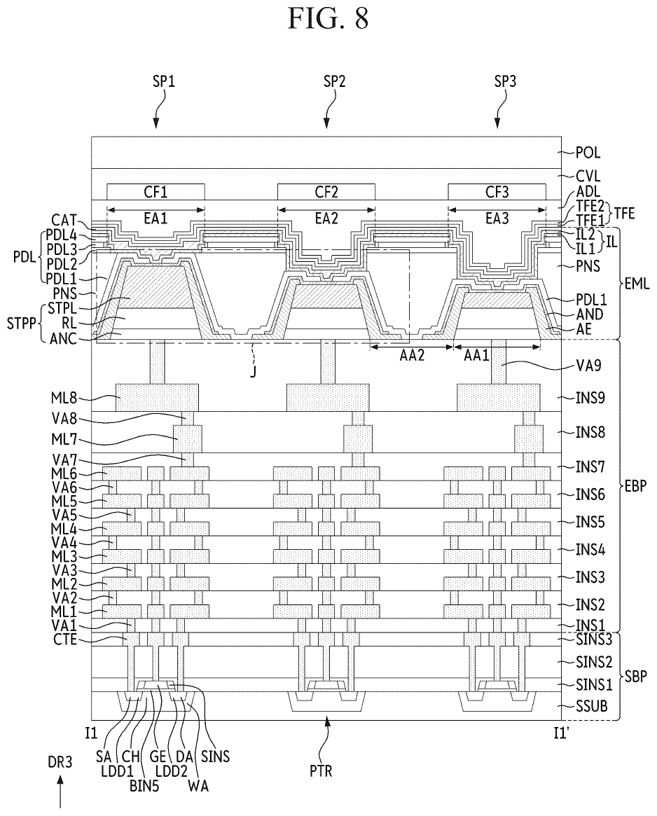

The light emitting stack IL may include a plurality of stack layers IL1, IL2, and IL3. It has been illustrated in FIG. 7 that the light emitting stack IL has a three-tandem structure including a first stack layer IL1, a second stack layer IL2, and a third stack layer IL3, but embodiments of the present disclosure are not limited thereto. For example, in one or more embodiments, the light emitting stack IL may have a two-tandem structure including two stack layers, as illustrated in FIG. 8.

In the three-tandem structure, in one or more embodiments, the light emitting stack IL may have a tandem structure including a plurality of stack layers IL1, IL2, and IL3 emitting different light. For example, the light emitting stack IL may include a first stack layer IL1 configured to emit first light, a second stack layer IL2 configured to emit second light, and a third stack layer IL3 configured to emit third light. The first stack layer IL1, the second stack layer IL2, and the third stack layer IL3 may be sequentially stacked (e.g., in the stated order).

The first stack layer IL1 may have a structure in which a first hole transporting layer, a first light emitting layer emitting the first light, and a first electron transporting layer are sequentially stacked (e.g., in the stated order). The second stack layer IL2 may have a structure in which a second hole transporting layer, a second light emitting layer emitting the second light, and a second electron transporting layer are sequentially stacked (e.g., in the stated order). The third stack layer IL3 may have a structure in which a third hole transporting layer, a third organic light emitting layer emitting the third light, and a third electron transporting layer are sequentially stacked (e.g., in the stated order).

A first charge generation layer for supplying charges (e.g., holes) to the second stack layer IL2 and supplying electrons to the first stack layer IL1 may be arranged between the first stack layer IL1 and the second stack layer IL2. The first charge generation layer may include an N-type (kind) charge generation layer supplying electrons to the first stack layer IL1 and a P-type (kind) charge generation layer supplying holes to the second stack layer IL2. The N-type (kind) charge generation layer may include a dopant of a metal material.

A second charge generation layer for supplying charges (e.g., holes) to the third stack layer IL3 and supplying electrons to the second stack layer IL2 may be arranged between the second stack layer IL2 and the third stack layer IL3. The second charge generation layer may include an N-type (kind) charge generation layer supplying electrons to the second stack layer IL2 and a P-type (kind) charge generation layer supplying holes to the third stack layer IL3.

The first stack layer IL1 may be arranged on the first electrodes AND and the pixel defining film PDL, and a residual film RIL arranged on a bottom surface of each of the trenches TRC may be made of a same material as the first stack layer IL1. Due to the trenches TRC, the first stack layer IL1 may be disconnected between the sub-pixels SP1, SP2, and SP3 neighboring to each other. The second stack layer IL2 may be arranged on the first stack layer IL1. Due to the trenches TRC, the second stack layer IL2 may be disconnected between the sub-pixels SP1, SP2, and SP3 neighboring to each other. A cavity ESS or an empty space may be arranged between the residual film RIL and the second stack layer IL2 in each of the trenches TRC. The third stack layer IL3 may be arranged on the second stack layer IL2. The third stack layer IL3 may not be disconnected by the trenches TRC, and may cover the second stack layer IL2 in each of the trenches TRC.

In the three-tandem structure, each of the plurality of trenches TRC may be a structure for disconnecting the first to second hole transporting layers of the first to second stack layers IL1, and IL2, and the first charge generation layer of the display element layer EML between the sub-pixels SP1, SP2, and SP3 neighboring to each other. In addition, in the two-tandem structure, each of the plurality of trenches TRC may be a structure for disconnecting a charge generation layer arranged between a lower stack layer and an upper stack layer and the lower stack layer.

In order to stably disconnect the first and second stack layers IL1 and IL2 of the display element layer EML between the sub-pixels SP1, SP2, and SP3 neighboring to each other, a height of each of the plurality of trenches TRC may be greater than a height of the pixel defining film PDL. The height of each of the plurality of trenches TRC refers to a length of each of the plurality of trenches TRC in the third direction DR3. The height of the pixel defining film PDL refers to a length of the pixel defining film PDL in the third direction DR3. In order to disconnect the hole transporting layers of the light emitting stack IL and the charge generation layers of the display element layer EML between the sub-pixels SP1, SP2, and SP3 neighboring to each other, other structures may be used instead of the trenches TRC. For example, instead of the trenches TRC, partition walls having a reverse tapered shape may be arranged on the pixel defining film PDL.

In addition, it has been illustrated in FIG. 7 that the light emitting stack IL that emits the light is arranged in all of the first emission area EA1, the second emission area EA2, and the third emission area EA3, but embodiments of the present disclosure are not limited thereto. For example, in one or more embodiments, instead of the light emitting stack IL, a first light emitting layer may be arranged in the first emission area EA1, and may not be arranged in the second emission area EA2 and the third emission area EA3. In addition, a second light emitting layer may be arranged in the second emission area EA2, and may not be arranged in the first emission area EA1 and the third emission area EA3. In addition, a third light emitting layer may be arranged in the third emission area EA3, and may not be arranged in the first emission area EA1 and the second emission area EA2. In these embodiments, first to third color filters CF1, CF2, and CF3 of the optical layer OPL may not be provided.

The second electrode CAT may be arranged on the light emitting stack IL. The second electrode CAT may be arranged on the third stack layer IL3 in each of the plurality of trenches TRC. In one or more embodiments, the second electrode CAT may be made of a transparent conductive material (TCO) such as indium tin oxide (ITO) or indium zinc oxide (IZO) capable of transmitting light or a semi-transmissive conductive material such as magnesium (Mg), silver (Ag), or an alloy of magnesium (Mg) and silver (Ag). When the second electrode CAT is made of the semi-transmissive conductive material, light emission efficiency of each of the first to third sub-pixels SP1, SP2, and SP3 may increase by a micro-cavity effect.

The encapsulation layer TFE may be arranged on the display element layer EML. The encapsulation layer TFE may include at least one inorganic film TFE1 or TFE2 in order to prevent or reduce oxygen and/or moisture from permeating into the display element layer EML. For example, in one or more embodiments, a first encapsulation inorganic film TFE1 may be arranged on the second electrode CAT, and a second encapsulation inorganic film TFE2 may be arranged on the first encapsulation inorganic film TFE1. The first encapsulation inorganic film TFE1 and the second encapsulation inorganic film TFE2 may be each independently formed as multiple films in which one or more inorganic films selected from among a silicon nitride (SiNₓ) layer, a silicon oxynitride (SiON) layer, a silicon oxide (SiOₓ) layer, a titanium oxide (TiOₓ) layer, and an aluminum oxide (AlOₓ) layer are alternately stacked.

In one or more embodiments, the encapsulation layer TFE may further include at least one organic film in order to protect the display element layer EML from foreign substances such as dust. The at least one organic film of the encapsulation layer TFE may be arranged between the first encapsulation inorganic film TFE1 and the second encapsulation inorganic film TFE2. In one or more embodiments, the at least one organic film of the encapsulation layer TFE may be made of a monomer. In one or more embodiments, the at least one organic film of the encapsulation layer TFE may be an organic film made of an acrylic resin, an epoxy resin, a phenolic resin, a polyamide resin, a polyimide resin, and/or the like.

An adhesive layer ADL may be a layer for adhering the encapsulation layer TFE and the optical layer OPL to each other. In one or more embodiments, the adhesive layer ADL may be a double-sided adhesive member. In addition, the adhesive layer ADL may be a transparent adhesive member such as a transparent adhesive or a transparent adhesive resin.

The optical layer OPL may include a plurality of color filters CF1, CF2, and CF3, a plurality of lenses LNS, a filling layer FIL, and a cover layer CVL. The plurality of color filters CF1, CF2, and CF3 may include first to third color filters CF1, CF2, and CF3. The first to third color filters CF1, CF2, and CF3 may be arranged on the adhesive layer ADL.

The first color filter CF1 may overlap the first emission area EA1 of the first sub-pixel SP1. The first color filter CF1 may be to transmit light of a first color, that is, light of a blue wavelength band. The blue wavelength band may be approximately about 370 nm to about 460 nm. Therefore, the first color filter CF1 may be to transmit the light of the first color among light emitted from the first emission area EA1.

The second color filter CF2 may overlap the second emission area EA2 of the second sub-pixel SP2. The second color filter CF2 may be to transmit light of a second color, that is, light of a green wavelength band. The green wavelength band may be approximately about 480 nm to about 560 nm. Therefore, the second color filter CF2 may be to transmit the light of the second color among light emitted from the second emission area EA2.

The third color filter CF3 may overlap the third emission area EA3 of the third sub-pixel SP3. The third color filter CF3 may be to transmit light of a third color, that is, light of a red wavelength band. The blue wavelength band may be approximately about 600 nm to about 750 nm. Therefore, the third color filter CF3 may be to transmit the light of the third color among light emitted from the third emission area EA3.

Each of the plurality of lenses LNS may be arranged on each of the first color filter CF1, the second color filter CF2, and the third color filter CF3, correspondingly. Each of the plurality of lenses LNS may be a structure for increasing a ratio of light directed to a front surface of the display device 10. In one or more embodiments, each of the plurality of lenses LNS may have a cross-sectional shape convex in an upward direction.

The filling layer FIL may be arranged on the plurality of lenses LNS. The filling layer FIL may have a selected refractive index so that light travels in the third direction DR3 at an interface between the plurality of lenses LNS and the filling layer FIL. In addition, the filling layer FIL may also be a planarizing layer. The filling layer FIL may be an organic film made of an acrylic resin, an epoxy resin, a phenolic resin, a polyamide resin, a polyimide resin, and/or the like.

The cover layer CVL may be arranged on the filling layer FIL. The cover layer CVL may be a glass substrate or a polymer resin such as a resin. In one or more embodiments, when the cover layer CVL is the glass substrate, the cover layer CVL may be attached onto the filling layer FIL. In these embodiments, the filling layer FIL may serve to adhere the cover layer CVL. When the cover layer CVL is the glass substrate, the cover layer CVL may also serve as an encapsulation substrate. In one or more embodiments, when the cover layer CVL is the polymer resin such as a resin, the cover layer CVL may be directly applied onto the filling layer FIL.

The polarizing plate POL may be arranged on a (e.g., one) surface of the cover layer CVL. The polarizing plate may be a structure for preventing or reducing deterioration in visibility due to external light reflection. The polarizing plate may include a linear polarizing plate and a phase retardation film. For example, in one or more embodiments, the phase retardation film may be a λ/4 plate (quarter-wave plate), but embodiments of the present disclosure are not limited thereto. However, if (e.g., when) visibility due to external light reflection is sufficiently improved by the first to third color filters CF1, CF2, and CF3, the polarizing plate may not be provided.

FIG. 8 is a cross-sectional view illustrating another example of the display panel taken along the line I1-I1′ of FIG. 5 according to one or more embodiments of the present disclosure. FIG. 8 is a cross-sectional view illustrating a display device according to a first embodiment of the present disclosure.

The embodiment of FIG. 8 is different from the embodiment of FIG. 7 in that the first electrode AND of each of the light emitting elements LE is in contact with and electrically connected to a side surface of a connection electrode ANC connected to the eighth conductive layer ML8. In addition, the embodiment of FIG. 8 is different from the embodiment of FIG. 7 in that the trench TRC is not provided and instead, a third pixel defining film PDL3 and a fourth pixel defining film PDL4 having a cross-sectional structure with an eaves shape or a mushroom shape are utilized. In one or more embodiments of FIG. 8, a description of content overlapping those of embodiments of FIG. 7 is not repeated for conciseness.

Referring to FIG. 8, a plurality of connection electrodes ANC may be arranged on first portions AA1 of the ninth insulating film INS9, respectively. Each of the plurality of connection electrodes ANC may be arranged on the first portion AA1 of the ninth insulating film INS9 corresponding thereto. Each of the plurality of connection electrodes ANC may be made of any one selected from among copper (Cu), aluminum (Al), tungsten (W), molybdenum (Mo), chromium (Cr), gold (Au), titanium (Ti), nickel (Ni), and neodymium (Nd), or an alloy thereof or a compound thereof, or a transparent conductive oxide. For example, in one or more embodiments, each of the plurality of connection electrodes ANC may include titanium (Ti), titanium nitride (TiN), ITO, or IZO, but embodiments of the present disclosure are not limited thereto.

A plurality of reflective electrodes RL may be respectively arranged on the plurality of connection electrodes ANC. Each of the plurality of reflective electrodes RL may be arranged on the connection electrode ANC corresponding thereto. Each of the plurality of reflective electrodes RL may be made of any one selected from among copper (Cu), aluminum (Al), tungsten (W), molybdenum (Mo), chromium (Cr), gold (Au), titanium (Ti), nickel (Ni), and neodymium (Nd), or an alloy thereof or a compound thereof. For example, in one or more embodiments, each of the plurality of reflective electrodes RL may include aluminum (Al) having high reflectivity.

A plurality of step layers STPL may be respectively arranged on the plurality of reflective electrodes RL. Each of the plurality of step layers STPL may be arranged on the reflective electrode RL corresponding thereto. Each of the plurality of step layers STPL may be formed as a silicon oxide (SiOₓ)-based inorganic film, but embodiments of the present disclosure are not limited thereto. The step layer STPL may be arranged on the reflective electrode RL in each of the first emission area EA1 to the third emission area EA3.

Due to the step layers STPL, a distance between the reflective electrode RL and the first electrode AND in the first emission area EA1 may be greater than a distance between the reflective electrode RL and the first electrode AND in the second emission area EA2. In addition, the distance between the reflective electrode RL and the first electrode AND in the second emission area EA2 may be greater than a distance between the reflective electrode RL and the first electrode AND in the third emission area EA3. However, embodiments of the present disclosure are not limited thereto. For example, a distance between the reflective electrode RL and the first electrode AND in the first emission area EA1 may be different from a distance between the reflective electrode RL and the first electrode AND in the second emission area EA2. In addition, the distance between the reflective electrode RL and the first electrode AND in the second emission area EA2 may be different from a distance between the reflective electrode RL and the first electrode AND in the third emission area EA3.

A thickness of the step layer STPL may be set in consideration of a wavelength and a resonance distance of light emitted from a first stack layer IL1 of the light emitting stack IL and a wavelength and a resonance distance of light emitted from a second stack layer IL2 of the light emitting stack IL.

Each of the light emitting elements LE may include the first electrode AND, the light emitting stack IL, and the second electrode CAT.

The first electrode AND of each of the light emitting elements LE may be arranged on the step layer STPL corresponding thereto. Because the connection electrode ANC, the reflective electrode RL, and the step layer STPL are sequentially stacked, the first electrode AND of each of the light emitting elements LE may be arranged on an upper surface and side surfaces of the step layer STPL, side surfaces of the reflective electrode RL, and side surfaces of the connection electrode ANC. For this reason, the first electrode AND of each of the light emitting elements LE may be in contact with and electrically connected to the side surfaces of the reflective electrode RL and the side surfaces of the connection electrode ANC. Therefore, there is an advantage that the number of mask processes may be reduced compared to a case in which the first electrode AND of each of the light emitting elements LE is connected to the reflective electrode RL exposed through a through hole penetrating through the step layer STPL, and thus, a manufacturing cost may be reduced and manufacturing efficiency may be increased.

In the display device according to one or more embodiments of the present disclosure, an auxiliary electrode AE may be arranged on an upper surface and side surfaces of a step portion STPP including the connection electrode ANC, the reflective electrode RL, and the step layer STPL. The auxiliary electrode AE may be arranged between the step portion STPP and the first electrode AND.

The first electrode AND of each of the light emitting elements LE may be connected to the drain region DA or the source region SA of the pixel transistor PTR through the connection electrode ANC, the first to ninth vias VA1 to VA9, the first to eighth conductive layers ML1 to ML8, and the contact terminal CTE.

The ninth insulating film INS9 may include the first portion AA1 that overlaps the connection electrode ANC in the third direction DR3 and a second portion AA2 that does not overlap the connection electrode ANC in the third direction DR3. In one or more embodiments, a thickness of the first portion AA1 and a thickness of the second portion AA2 of the ninth insulating film INS9 may be substantially the same as each other.

In one or more embodiments, a thickness of the first portion AA1 of the ninth insulating film INS9 may be greater than a thickness of the second portion AA2 of the ninth insulating film INS9. In these embodiments, side surfaces of the first portion AA1 of the ninth insulating film INS9 may be exposed, and the first electrode AND of each of the light emitting elements LE may be arranged on the exposed side surfaces of the first portion AA1 of the ninth insulating film INS9.

The first electrode AND of each of the light emitting elements LE may be made of any one selected from among copper (Cu), aluminum (Al), tungsten (W), molybdenum (Mo), chromium (Cr), gold (Au), titanium (Ti), nickel (Ni), and neodymium (Nd), or an alloy thereof or a compound thereof, or a transparent conductive oxide. For example, in one or more embodiments, the first electrode AND of each of the light emitting elements LE may include titanium nitride (TiN), ITO, or IZO, but embodiments of the present disclosure are not limited thereto.

The pixel defining film PDL may be arranged on a partial area of the first electrode AND of each of the light emitting elements LE. The pixel defining film PDL may cover an edge of the first electrode AND of each of the light emitting elements LE. The pixel defining film PDL may partition the first emission areas EA1, the second emission areas EA2, and the third emission areas EA3.

The pixel defining film PDL may include first to fourth pixel defining films PDL1, PDL2, PDL3, and PDL4.

The first pixel defining film PDL1 may be arranged on (e.g., partially on) the first electrode AND of each of the light emitting elements LE. For example, the first pixel defining film PDL1 may cover a partial area of an upper surface of the first electrode AND arranged on the step layer STPL. In addition, the first pixel defining film PDL1 may cover the first electrode AND arranged on the side surfaces of the connection electrode ANC, the side surfaces of the reflective electrode RL, and the side surfaces of the step layer STPL. The first pixel defining film PDL1 may be arranged on an upper surface of the second portion AA2 of the ninth insulating film INS9.

A planarizing film PNS is a film for planarizing a step caused by the connection electrode ANC, the reflective electrode RL, and the step layer STPL.

The planarizing film PNS may be arranged on the first pixel defining film PDL1 covering the first electrode AND arranged on the side surfaces of the connection electrode ANC, the side surfaces of the reflective electrode RL, and the side surfaces of the step layer STPL. The planarizing film PNS may be arranged on the first pixel defining film PDL1 covering the first electrode AND arranged on the side surfaces of the step portion STPP. The planarizing film PNS may be arranged on the first pixel defining film PDL1 arranged on the second portion AA2 of the ninth insulating film INS9.

The planarizing film PNS may be arranged between the connection electrodes ANC neighboring to each other in the first direction DR1 or the second direction DR2. The planarizing film PNS may be arranged between the reflective electrodes RL neighboring to each other in the first direction DR1 or the second direction DR2. The planarizing film PNS may be arranged between the step layers STPL neighboring to each other.

Due to a height difference between the step layers STPL, the planarizing film PNS may cover (e.g., partially cover) upper surfaces of the first pixel defining films PDL1 arranged on upper surfaces of the first electrodes AND arranged in the second emission area EA2 and the third emission area EA3.

An upper surface of the planarizing film PNS may be flatly connected to an upper surface of the first pixel defining film PDL1 in the first emission area EA1. For example, the planarizing film PNS may not cover the upper surface of the first pixel defining film PDL1 arranged on the upper surface of the first electrode AND arranged in the first emission area EA1.

The second pixel defining film PDL2 may be arranged on the first pixel defining film PDL1 and the planarizing film PNS, the third pixel defining film PDL3 may be arranged on the second pixel defining film PDL2, and the fourth pixel defining film PDL4 may be arranged on the third pixel defining film PDL3. In one or more embodiments, the first pixel defining film PDL1 and the third pixel defining film PDL3 may each be formed as a silicon nitride (SiNₓ)-based inorganic film, whereas the second pixel defining film PDL2, the fourth pixel defining film PDL4, and the planarizing film PNS may each be formed as a silicon oxide (SiOₓ)-based inorganic film. The first pixel defining film PDL1 is made of a different material from the planarizing film PNS, and may thus serve as a stopper in a process of chemically and mechanically polishing the planarizing film PNS.

When both (e.g., simultaneously) the planarizing film PNS and the second pixel defining film PDL2 are each formed as the silicon oxide (SiOₓ)-based inorganic film, the planarizing film PNS and the second pixel defining film PDL2 may be formed as a single film.

Because a length of the third pixel defining film PDL3 in one direction is smaller than a length of the fourth pixel defining film PDL4 in one direction, a lower surface of the fourth pixel defining film PDL4 may be partially exposed without being covered by the third pixel defining film PDL3. For example, the third pixel defining film PDL3 and the fourth pixel defining film PDL4 may have a cross-sectional structure with an eaves shape or a mushroom shape.

The light emitting stack IL may be arranged on the first electrode AND and the pixel defining film PDL. The light emitting stack IL may include a first stack layer IL1 and a second stack layer IL2 that emit different light. In one or more embodiments, when the light emitting stack IL has a two-tandem structure, one selected from among the first stack layer IL1 and the second stack layer IL2 may be to emit light including a wavelength range of one selected from among the first light, the second light, and the third light, and the other of (e.g., selected from among) the first stack layer IL1 and the second stack layer IL2 may be to emit light including wavelength ranges of the other two of the first light, the second light, and the third light. For example, in one or more embodiments, the first stack layer IL1 may be to emit light including a wavelength range of the first light and a wavelength range of the third light, and the second stack layer IL2 may be to emit light including a wavelength range of the second light. Here, the first light may be light of a blue wavelength band, the second light may be light of a green wavelength band, and the third light may be light of a red wavelength band.

A charge generation layer for supplying charges (e.g., holes) to the second stack layer IL2 and supplying electrons to the first stack layer IL1 may be arranged between the first stack layer IL1 and the second stack layer IL2. The charge generation layer may include an N-type (kind) charge generation layer supplying electrons to the first stack layer IL1 and a P-type (kind) charge generation layer supplying holes to the second stack layer IL2. The N-type (kind) charge generation layer may include a dopant of a metal material.

The first stack layer IL1 may not be formed on the lower surface of the fourth pixel defining film PDL4 exposed without being covered by the third pixel defining film PDL3, and may thus be disconnected by the cross-sectional structure with the eaves shape or the mushroom shape by the third pixel defining film PDL3 and the fourth pixel defining film PDL4. In this regard, a first hole transporting layer of the first stack layer IL1 and the charge generation layer arranged between the first stack layer IL1 and the second stack layer IL2 may also be disconnected. In addition, it has been illustrated in FIG. 8 that the second stack layer IL2 is not disconnected and is connected, but a second hole transporting layer of the second stack layer IL2 may be disconnected, and a second electron transporting layer of the second stack layer IL2 is not disconnected and may be connected. Therefore, it may prevent or reduce a lateral leakage from flowing through the first hole transporting layer of the first stack layer IL1, the second hole transporting layer of the second stack layer IL2, and the charge generation layer between the emission areas EA1, EA2, and EA3 neighboring to each other. Accordingly, it may prevent or reduce the light emitting stack IL in the emission areas EA1, EA2, and EA3 neighboring to each other from being affected by the lateral leakage and emitting light other than originally intended light.

It has been illustrated in FIG. 8 that the light emitting stack IL has the two-tandem structure including two stack layers IL1 and IL2, but embodiments of the present disclosure are not limited thereto. For example, in one or more embodiments, the light emitting stack IL may have a three-tandem structure including three stack layers, as illustrated in FIG. 7. In these embodiments, by adjusting a height of the third pixel defining film PDL3, a charge generation layer between the first stack layer IL1 and the second stack layer IL2 and a charge generation layer between the second stack layer IL2 and the third stack layer IL3 may be designed to be disconnected. In one or more embodiments, as illustrated in FIG. 7, a trench penetrating through the first pixel defining film PDL1, the planarizing film PNS, the second pixel defining film PDL2, and the third pixel defining film PDL3 may be added. In this regard, the trench may penetrate through at least a portion of the ninth insulating film INS9, but embodiments of the present disclosure are not limited thereto.

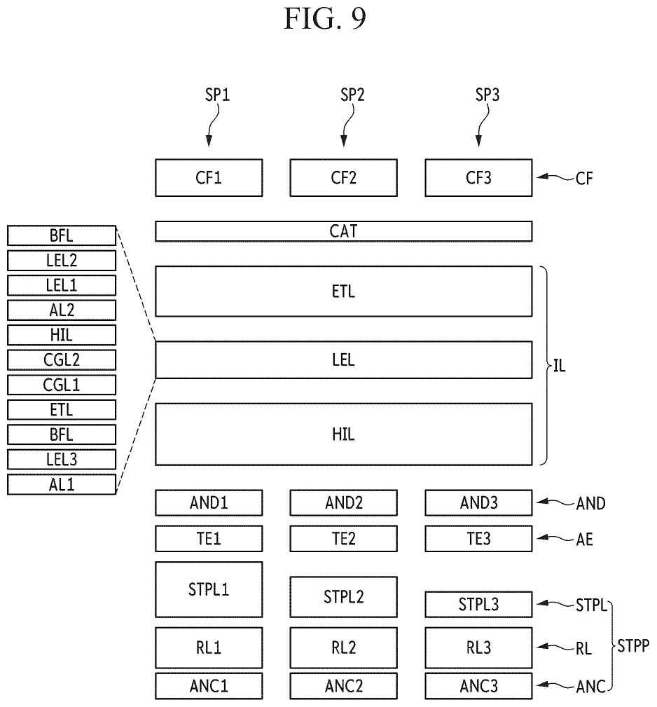

FIG. 9 is a schematic block diagram illustrating components included in the display device according to one or more embodiments of the present disclosure.

Referring to FIG. 9, a plurality of connection electrodes ANC, a plurality of reflective electrodes RL, a plurality of step layers STPL, a plurality of auxiliary electrodes AE, a plurality of first electrodes AND, and a plurality of color filters CF may be located to respectively correspond to a plurality of sub-pixels SP1, SP2, and SP3 including a first sub-pixel SP1, a second sub-pixel SP2, and a third sub-pixel SP3.

The plurality of connection electrodes ANC may include a first connection electrode ANC1, a second connection electrode ANC2, and a third connection electrode ANC3.

The plurality of reflective electrodes RL may include a first reflective electrode RL1 located to correspond to the first connection electrode ANC1, a second reflective electrode RL2 located to correspond to the second connection electrode ANC2, and a third reflective electrode RL3 located to correspond to the third connection electrode ANC3.

The plurality of step layers STPL may include a first step layer STPL1 located to correspond to the first connection electrode ANC1, a second step layer STPL2 located to correspond to the second connection electrode ANC2, and a third step layer STPL3 located to correspond to the third connection electrode ANC3. Heights of the plurality of step layers STPL may be different from one another in the first sub-pixel SP1, the second sub-pixel SP2, and the third sub-pixel SP3.

The plurality of auxiliary electrodes AE may include a first taper forming angle adjusting electrode TE1 located to correspond to the first connection electrode ANC1, a second taper forming angle adjusting electrode TE2 located to correspond to the second connection electrode ANC2, and a third taper forming angle adjusting electrode TE3 located to correspond to the third connection electrode ANC3.

The plurality of first electrodes AND may include a first anode electrode AND1 located to correspond to the first connection electrode ANC1, a second anode electrode AND2 located to correspond to the second connection electrode ANC2, and a third anode electrode AND3 located to correspond to the third connection electrode ANC3.

The plurality of reflective electrodes RL may be respectively arranged on the plurality of connection electrodes ANC. The plurality of step layers STPL may be respectively arranged on the plurality of reflective electrodes RL. The plurality of auxiliary electrodes AE may be respectively arranged on the plurality of step layers STPL. The plurality of first electrodes AND may be respectively arranged on the plurality of auxiliary electrodes AE.

A light emitting stack IL may be arranged on the plurality of first electrodes AND, and may include a hole injecting layer or transporting layer HIL, a sub-light emitting layer LEL, and an electron injecting layer or transporting layer ETL.

A second electrode CAT may be arranged on the light emitting stack IL, and the plurality of color filters CF may be arranged on the second electrode CAT.

In one or more embodiments, the hole injecting layer or transporting layer HIL, the sub-light emitting layer LEL, the electron injecting layer or transporting layer ETL, and the second electrode CAT may be formed in common in the first sub-pixel SP1, the second sub-pixel SP2, and the third sub-pixel SP3. This is different from the plurality of auxiliary electrodes AE individually formed in the first sub-pixel SP1, the second sub-pixel SP2, and the third sub-pixel SP3.

The sub-light emitting layer LEL may include a first auxiliary layer AL1, a third sub-light emitting stack LEL3, a buffer layer BFL, an electron injecting layer or transporting layer ETL, a first charge generation layer CGL1, a second charge generation layer CGL2, a second auxiliary layer AL2, a first sub-light emitting stack LEL1, a second sub-light emitting stack LEL2, and a buffer layer BFL.

The auxiliary layers AL1 and AL2 and the buffer layer BFL may perform auxiliary functions. In one or more embodiments and modified examples, each of the first auxiliary layer AL1, the second auxiliary layer AL2, and the buffer layer BFL may perform a blocking function for blocking carriers (e.g., electrons). In one or more embodiments, the first auxiliary layer AL1, the second auxiliary layer AL2, and the buffer layer BFL may be layers for balancing a thickness and/or a height. In one or more embodiments, each of the first auxiliary layer AL1, the second auxiliary layer AL2, and the buffer layer BFL may also perform a function for promoting injection of carriers (e.g., holes).

The first charge generation layer CGL1 may be a negative charge generation layer (n-CGL). The second charge generation layer CGL2 may be a positive charge generation layer (p-CGL). Each of the first charge generation layer CGL1 and the second charge generation layer CGL2 may include a host and a dopant. The host may include an organic material.

A negative charge supplied from the first charge generation layer CGL1 may move toward the third sub-light emitting stack LEL3 and combine with a positive charge supplied from the first electrode AND, and accordingly, an exciton may be generated (e.g., in the third sub-light emitting stack LEL3). A positive charge supplied from the second charge generation layer CGL2 may move toward the first sub-light emitting stack LEL1 and the second sub-light emitting stack LEL2 and combine with a negative charge supplied from the second electrode CAT, and accordingly, an exciton may be generated (e.g., in the first sub-light emitting stack LEL1 or the second sub-light emitting stack LEL2). The negative charge may be an electron, and the positive charge may be a hole. In reality, only the electron moves, but for the convenience of explanation, a description will hereinafter be provided on the assumption that the hole also moves.

The sub-light emitting layer LEL according to one or more embodiments may have a two-tandem structure including two stack layers. For example, the light emitting stack IL may include a first stack layer and a second stack layer. The first stack layer may include the hole injecting layer or transporting layer HIL, the first auxiliary layer AL1, the third sub-light emitting stack LEL3, the buffer layer BFL, the electron injecting layer or transporting layer ETL, the first charge generation layer CGL1, and the second charge generation layer CGL2. The second stack layer may include the hole injecting layer or transporting layer HIL, the second auxiliary layer AL2, the first sub-light emitting stack LEL1, the second sub-light emitting stack LEL2, the buffer layer BFL, and the electron injecting layer or transporting layer ETL.

A criterion for distinguishing the first stack layer and the second stack layer from each other may be the number of groups in grouped sub-light emitting stacks. A criterion for grouping the sub-light emitting stacks may be whether or not a layer other than a sub-light emitting stack is included between different sub-light emitting stacks. As an example, in one or more embodiments illustrated in FIG. 9, the third sub-light emitting stack LEL3 may be one group, and the first sub-light emitting stack LEL1 and the second sub-light emitting stack LEL2 may be the other group. The layer other than the sub-light emitting stack may not be included between the first sub-light emitting stack LEL1 and the second sub-light emitting stack LEL2.

In this regard, the sub-light emitting stacks may be grouped into two groups, and thus, the first stack layer and the second stack layer may be defined in one or more embodiments illustrated in FIG. 9. The first stack layer may include the third sub-light emitting stack LEL3, and the second stack layer may include the first sub-light emitting stack LEL1 and the second sub-light emitting stack LEL2. As long as each stack layer includes the above-described sub-light emitting stack, it may be changed according to an embodiment whether or not the layer other than the sub-light emitting stack is included. The sub-light emitting layer according to one or more embodiments illustrated in FIG. 9 may have a two-tandem structure.

Each of the first sub-light emitting stack LEL1, the second sub-light emitting stack LEL2, and the third sub-light emitting stack LEL3 may implement any one color selected from the group consisting of a red color, a green color, and a blue color so that these colors do not overlap each other. For example, in one or more embodiments, the first sub-light emitting stack LEL1 may implement the red color, the second sub-light emitting stack LEL2 may implement the green color, and the third sub-light emitting stack LEL3 may implement the blue color, but embodiments of the present disclosure are not limited thereto.

In one or more embodiments illustrated in FIG. 9, if (e.g., when) all of light emitted from the first sub-light emitting stack LEL1, light emitted from the second sub-light emitting stack LEL2, and light emitted from the third sub-light emitting stack LEL3 are mixed with each other, a substantially white color may be implemented. If (e.g., when) the white color is implemented in the light emitting stack IL formed in common, the emitted white light may implement a first color by passing through a first color filter CF1, implement a second color by passing through a second color filter CF2, or implement a third color by passing through a third color filter CF3. Each of the first color, the second color, and the third color may be any one color selected from the group consisting of the red color, the green color, and the blue color. In this regard, the selected colors may not overlap each other.

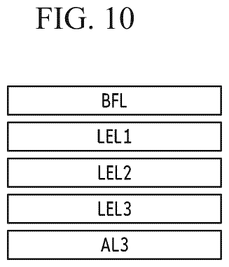

FIGS. 10 to 12 are each a schematic block diagram illustrating a modified example of a light emitting stack according to one or more embodiments of the present disclosure.

Referring to FIG. 10, a sub-light emitting layer may include any one stack layer. Any one group may include a first sub-light emitting stack LEL1, a second sub-light emitting stack LEL2, and a third sub-light emitting stack LEL3 between a third auxiliary layer AL3 and a buffer layer BFL. Because a layer other than a sub-light emitting stack is not included between the respective sub-light emitting stacks, the sub-light emitting stacks according to one or more embodiments illustrated in FIG. 10 may be grouped into one group. The sub-light emitting layer according to one or more embodiments illustrated in FIG. 10 may have a one-tandem structure.

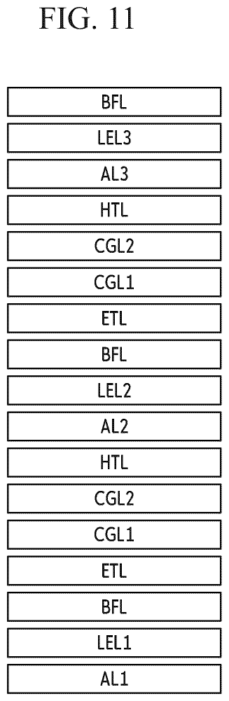

Referring to FIG. 11, a sub-light emitting layer may include three stack layers. One group may include a first sub-light emitting stack LEL1, another group may include a second sub-light emitting stack LEL2, and the other group may include a third sub-light emitting stack LEL3. Because layers (e.g., a first charge generation layer CGL1, and/or the like) other than a sub-light emitting stack are not included between the respective sub-light emitting stacks in the respective group, the sub-light emitting stacks according to one or more embodiments illustrated in FIG. 11 may be grouped into three groups. The sub-light emitting layer according to one or more embodiments illustrated in FIG. 11 may have a three-tandem structure.

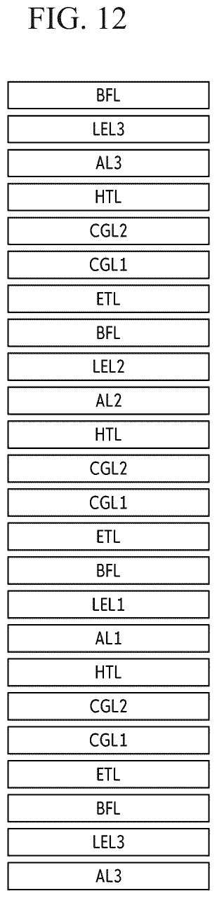

Referring to FIG. 12, a sub-light emitting layer may include four stack layers. One group may include a first sub-light emitting stack LEL1, another group may include a second sub-light emitting stack LEL2, a third group may include a third sub-light emitting stack LEL3, and a fourth group may include a third sub-light emitting stack LEL3. In one or more embodiments illustrated in FIG. 12, two groups including the third sub-light emitting stacks LEL3 may be defined. For example, light emitting efficiency of the third sub-light emitting stack LEL3 for a color implemented by the third sub-light emitting stack LEL3 may be lower than light emitting efficiency of the first sub-light emitting stack LEL1 and light emitting efficiency of the second sub-light emitting stack LEL2. In this way, a color gamut for a white color may be improved by forming a plurality of identical groups as illustrated in FIG. 12. Because layers (e.g., a first charge generation layer CGL1, and/or the like.) other than a sub-light emitting stack are not included between the respective sub-light emitting stacks in the respective group, the sub-light emitting stacks according to one or more embodiments illustrated in FIG. 12 may be grouped into four groups. The sub-light emitting layer according to one or more embodiments illustrated in FIG. 12 may have a four-tandem structure.

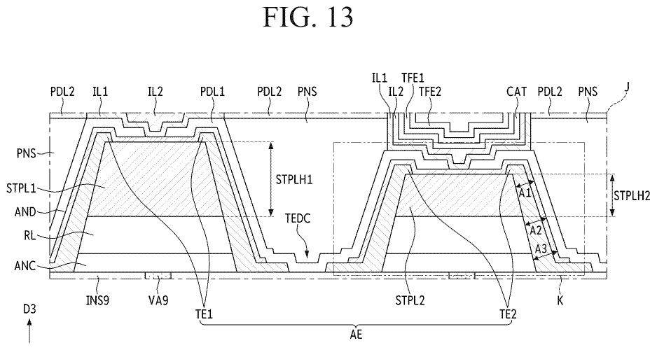

FIG. 13 is a partially enlarged view illustrating the portion J of FIG. 8 according to one or more embodiments of the present disclosure.

Referring to FIG. 13 in conjunction with FIG. 8, the display device includes a step portion STPP, a first electrode AND, a light emitting stack IL1 and IL2, and a second electrode CAT. The step portion STPP is defined by a plurality of side surfaces opposite to (e.g., facing) each other and a lower surface and an upper surface opposite to (e.g., facing) each other. The first electrode AND may be arranged on the upper surface of the step portion STPP and the plurality of side surfaces of the step portion STPP. The light emitting stack IL1 and IL2 may be arranged on the first electrode AND. The light emitting stack IL1 and IL2 may include a first stack layer IL1 and a second stack layer IL2, but embodiments of the present disclosure are not limited thereto.

The second electrode CAT may be arranged on the light emitting stack IL1 and IL2. In one or more embodiments, the first electrode AND may be an anode electrode, and the second electrode CAT may be a cathode electrode.

The step portion STPP may include a connection electrode ANC, a reflective electrode RL, and a step layer STPL. The connection electrode ANC may be defined by a plurality of side surfaces opposite to (e.g., facing) each other and a lower surface and an upper surface opposite to (e.g., facing) each other. The reflective electrode RL may be defined by a plurality of side surfaces opposite to (e.g., facing) each other and a lower surface and an upper surface opposite to (e.g., facing) each other. The step layer STPL may be defined by a plurality of side surfaces opposite to (e.g., facing) each other and a lower surface and an upper surface opposite to (e.g., facing) each other.

For example, the step layer STPL may include a first step layer STPL1 and a second step layer STPL2. The first step layer STPL1 may be located to correspond to the first emission area, and the second step layer STPL2 may be located to correspond to the second emission area. Thicknesses of the first step layer STPL1 and the second step layer STPL2 may be different from each other. For example, a first thickness STPLH1 of the first step layer STPL1 may be greater than a second thickness STPLH2 of the second step layer STPL2, but embodiments of the present disclosure are not limited thereto. The first thickness STPLH1 and the second thickness STPLH2 may be set in consideration of a wavelength and a resonance distance of light emitted from the first stack layer IL1 or the second stack layer IL2. A thickness of the step portion STPP may be changed by the thickness of the step layer STPL. For example, the first thickness STPLH1 and the second thickness STPLH2 may be each independently about 10 nm or more and about 300 nm or less.

An auxiliary electrode AE may be arranged between the first electrode AND and the step portion STPP for each emission area. The auxiliary electrode AE may include a plurality of taper forming angle adjusting electrodes TE1 and TE2 corresponding to the respective emission areas. For example, the auxiliary electrode AE may include a first taper forming angle adjusting electrode TE1 arranged between the first electrode AND and the first step layer STPL1, and a second taper forming angle adjusting electrode TE2 arranged between the first electrode AND and the second step layer STPL2.

The auxiliary electrode AE may be made of any one selected from among copper (Cu), aluminum (Al), tungsten (W), molybdenum (Mo), chromium (Cr), gold (Au), titanium (Ti), nickel (Ni), and neodymium (Nd), or an alloy thereof or a compound thereof. For example, in one or more embodiments, the auxiliary electrode AE may be made of titanium nitride (TiN). In one or more embodiments, the auxiliary electrode AE may include a same material as the first electrode AND, but embodiments of the present disclosure are not limited thereto.

The auxiliary electrode AE may serve to reduce a disconnection probability of the first electrode AND by adjusting a taper angle.

An auxiliary electrode disconnection portion TEDC may be formed between the first taper forming angle adjusting electrode TE1 and the second taper forming angle adjusting electrode TE2. If (e.g., when) the plurality of taper forming angle adjusting electrodes TE1 and TE2 are not disconnected from each other and are connected to each other, a lateral leakage may be generated, and the auxiliary electrode disconnection portion TEDC may reduce the lateral leakage by preventing or reducing carriers supplied from the first electrode AND from moving to another emission area (or to neighboring emission area).

A plurality of distances A1, A2, and A3 between the side surface of the step portion STPP and a side surface of the first electrode AND may be defined. In one or more embodiments, the distances A1, A2, and A3 between the side surface of the step portion STPP and the side surface of the first electrode AND may not be constant and may be different from one another.

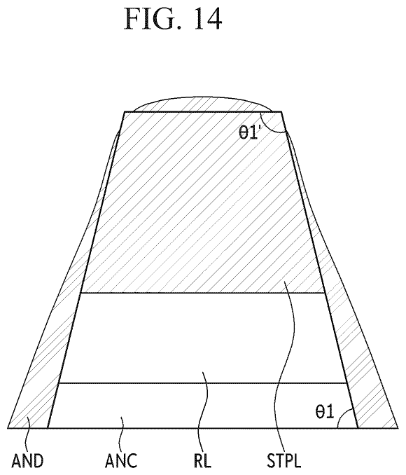

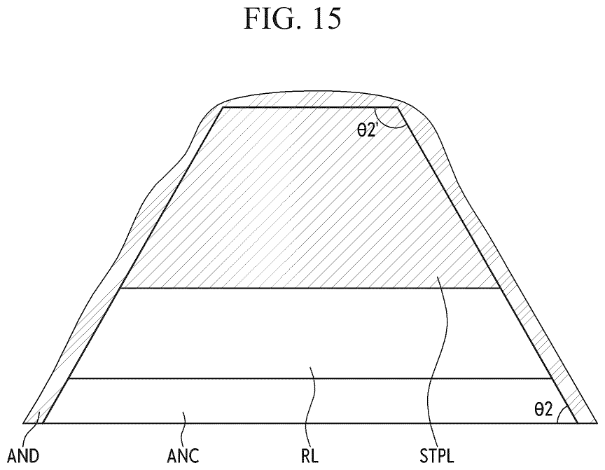

FIGS. 14 and 15 are each a cross-sectional view for describing a shape of a deposit according to a shape of a step portion according to one or more embodiments of the present disclosure.

Referring to FIG. 14, a first taper angle θ1 and a second taper angle θ1′ may be defined in the step portion including the connection electrode ANC, the reflective electrode RL, and the step layer STPL. The first taper angle θ1 may be defined by the side surface and the lower surface of the step portion. The second taper angle θ1′ may be defined by the side surface and the upper surface of the step portion. In one or more embodiments, the sum of the first taper angle θ1 and the second taper angle θ1′ may be a constant. If (e.g., when) the first taper angle θ1 increases, the second taper angle θ1′ may decrease, and if (e.g., when) the first taper angle θ1 decreases, the second taper angle θ1′ may increase. The first taper angle θ1 may be an acute angle, and the second taper angle θ1′ may be an obtuse angle.

In one or more embodiments, the first taper angle θ1 may be relatively great or large, and the second taper angle θ1′ may be relatively small. When the first taper angle θ1 is formed relatively great or large, the second taper angle θ1′ may be formed relatively small. Because the first taper angle θ1 is the acute angle, if (e.g., when) the first taper angle θ1 is formed relatively great or large, it may refer to that the first taper angle θ1 becomes relatively close to a right angle. Because the second taper angle θ1′ is the obtuse angle, if (e.g., when) the second taper angle θ1′ is formed relatively small, it may refer to that the second taper angle θ1′ becomes relatively close to a right angle.

The first electrodes AND may be arranged on the side surfaces and the upper surface of the step portion. When the second taper angle θ1′ is the obtuse angle and formed relatively close to the right angle (or formed relatively small), the first electrodes AND arranged on the upper surface and the side surface of the step portion may be disconnected from each other. The first electrode AND may transfer carriers supplied through the connection electrode ANC to the light emitting stack arranged on the first electrode AND. If (e.g., when) the first electrode AND arranged on the upper surface of the step portion and the first electrode AND arranged on the side surface of the step portion are disconnected from each other, the carriers may not be transferred. In addition, a thickness of an electrode may decrease around a disconnected portion or a corner portion, such that a current may not flow smoothly even if the disconnection is not complete. In one or more embodiments, the carrier may be a positive charge, but embodiments of the present disclosure are not limited thereto.

Referring to FIG. 15, a third taper angle θ2 and a fourth taper angle θ2′ may be defined in the step portion including the connection electrode ANC, the reflective electrode RL, and the step layer STPL. The third taper angle θ2 may be defined by the side surface and the lower surface of the step portion. The fourth taper angle θ2′ may be defined by the side surface and the upper surface of the step portion.

In one or more embodiments, the sum of the third taper angle θ2 and the fourth taper angle θ2′ may be a constant. If (e.g., when) the third taper angle θ2 increases, the fourth taper angle θ2′ may decrease, and if (e.g., when) the third taper angle θ2 decreases, the fourth taper angle θ2′ may increase. The third taper angle θ2 may be an acute angle, and the fourth taper angle θ2′ may be an obtuse angle.

In one or more embodiments, the third taper angle θ2 may be relatively small, and the fourth taper angle θ2′ may be relatively great or large. When the third taper angle θ2 is formed relatively small, the fourth taper angle θ2′ may be formed relatively great or large. Because the fourth taper angle θ2′ is the obtuse angle, if (e.g., when) the fourth taper angle θ2′ is formed relatively great or large, it may refer to that the fourth taper angle θ2′ becomes relatively close to 180°. Because the third taper angle θ2 is the acute angle, if (e.g., when) the third taper angle θ2 is formed relatively small, it may refer to that the third taper angle θ2 becomes relatively close to 0°.

The first electrodes AND may be arranged on the side surfaces and the upper surface of the step portion. If (e.g., when) the fourth taper angle θ2′ is the obtuse angle and formed relatively close to 180° (or formed relatively great or large), the first electrodes AND arranged on the upper surface and the first electrodes AND arranged on the side surface of the step portion may be connected to each other. The first electrode AND may transfer carriers supplied through the connection electrode ANC to the light emitting stack arranged on the first electrode AND. If (e.g., when) the first electrode AND arranged on the upper surface of the step portion and the first electrode AND arranged on the side surface of the step portion are connected to each other, the carriers may be smoothly transferred. In one or more embodiments, the carrier may be a positive charge, but an embodiment of the present disclosure is not limited thereto.

Referring to FIGS. 14 and 15, in the display device according to one or more embodiments of the present disclosure, it may reduce a disconnection probability of the first electrode AND arranged on the step portion by adjusting the taper angle. Accordingly, light emitting efficiency of the display device may be increased, and power consumption of the display device may be reduced.

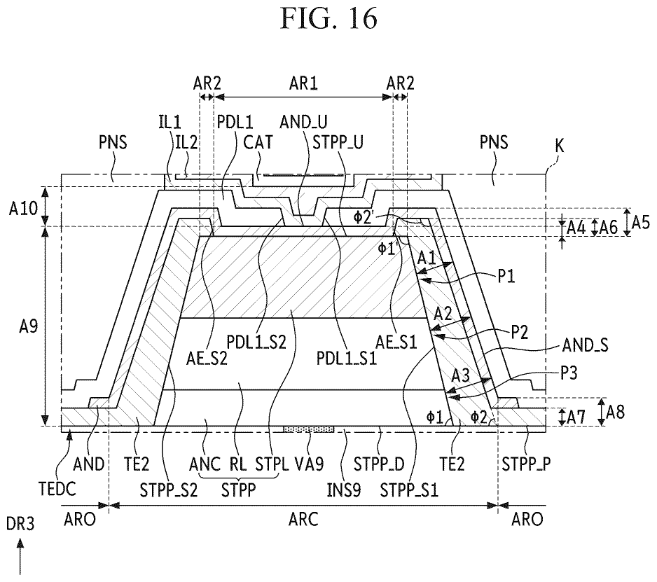

FIG. 16 is a partially enlarged view illustrating the portion K of FIG. 13 according to one or more embodiments of the present disclosure.

Referring to FIG. 16, the step portion STPP may be defined by a first side surface STPP_S1 and a second side surface STPP_S2 opposite to (e.g., facing) each other and an upper surface STPP_U and a lower surface STPP_D opposite to (e.g., facing) each other. For example, the first side surface STPP_S1 of the step portion STPP and the lower surface STPP_D of the step portion STPP may form a first angle Φ1. For example, the first side surface STPP_S1 of the step portion STPP and the upper surface STPP_U of the step portion STPP may form a third angle Φ1′.

In one or more embodiments, in order to adjust a taper angle of the step portion STPP, a distance between the first side surface STPP_S1 of the step portion STPP and a side surface AND_S of the first electrode AND may not be constant on the side surface STPP_S1 of the step portion STPP. To this end, a second taper forming angle adjusting electrode TE2 may be arranged between the first electrode AND and the step portion STPP. The auxiliary electrode may include the second taper forming angle adjusting electrode TE2.

The second taper forming angle adjusting electrode TE2 may be made of any one selected from among copper (Cu), aluminum (Al), tungsten (W), molybdenum (Mo), chromium (Cr), gold (Au), titanium (Ti), nickel (Ni), and neodymium (Nd), or an alloy thereof or a compound thereof. For example, in one or more embodiments, the second taper forming angle adjusting electrode TE2 may be made of titanium nitride (TiN). The second taper forming angle adjusting electrode TE2 may include a same material as the first electrode AND, but embodiments of the present disclosure are not limited thereto.

The second taper forming angle adjusting electrode TE2 may serve to reduce a disconnection probability of the first electrode AND by adjusting the taper angle. In order to adjust the taper angle, the second taper forming angle adjusting electrode TE2 may be arranged on the side surface STPP_S1 of the step portion STPP and a plane STPP_P including the lower surface STPP_D of the step portion STPP. The second taper forming angle adjusting electrode TE2 may cover the side surface STPP_S1 of the step portion STPP and at least a portion of the plane STPP_P including the lower surface STPP_D of the step portion STPP.

Even if (e.g., when) the second taper forming angle adjusting electrode TE2 is arranged, an electrical role of the first electrode AND needs to be smoothly and suitably performed. Accordingly, the second taper forming angle adjusting electrode TE2 may have conductivity (e.g., electrical conductivity). For example, even though the second taper forming angle adjusting electrode TE2 is arranged between the first electrode AND and the step portion STPP, the first electrode AND may be electrically connected to the step portion STPP. For example, the first electrode AND may be electrically connected to the connection electrode ANC and/or the reflective electrode RL. In one or more embodiments, the second taper forming angle adjusting electrode TE2 may be made of titanium nitride (TiN), but a material of the second taper forming angle adjusting electrode TE2 is not limited as long as it has the electrical conductivity as described above.

The side surface STPP_S1 of the step portion STPP may include a first point P1, a second point P2, and a third point P3. The first point P1 may be relatively more adjacent to the upper surface STPP_U of the step portion STPP than the second point P2 and the third point P3 are. The second point P2 may be relatively more adjacent to the upper surface STPP_U of the step portion STPP than the third point P3 is. The third point P3 may be relatively more adjacent to the lower surface STPP_D of the step portion STPP than the first point P1 and the second point P2 are. The second point P2 may be relatively more adjacent to the lower surface STPP_D of the step portion STPP than the first point P1 is to the lower surface STPP_D.

A distance A1 between the first point P1 and the side surface AND_S of the first electrode AND, a distance A2 between the second point P2 and the side surface AND_S of the first electrode AND, and a distance A3 between the third point P3 and the side surface AND_S of the first electrode AND may be defined. Here, the distance may refer to a shortest distance between a point on the side surface STPP_S1 of the step portion STPP and the side surface AND_S of the first electrode AND. When the second taper forming angle adjusting electrode TE2 is arranged, these distances A1, A2, and A3 may be different from each other. For example, the distance A1 between the first point P1 and the side surface AND_S of the first electrode AND may be different from the distance A2 between the second point P2 and the side surface AND_S of the first electrode AND. The distance A2 between the second point P2 and the side surface AND_S of the first electrode AND may be different from the distance A3 between the third point P3 and the side surface AND_S of the first electrode AND. The distance A1 between the first point P1 and the side surface AND_S of the first electrode AND may be different from the distance A3 between the third point P3 and the side surface AND_S of the first electrode AND.

In one or more embodiments, the distance A1, A2, or A3 between any point on the side surface STPP_S1 of the step portion STPP and the side surface AND_S of the first electrode AND may gradually change from the first point P1 toward the third point P3 (or toward a point adjacent to the lower surface STPP_D of the step portion STPP) on the side surface STPP_S1 of the step portion STPP. For example, the distance A1, A2, or A3 between any point on the side surface STPP_S1 of the step portion STPP and the side surface AND_S of the first electrode AND may gradually increase from the first point P1 toward the third point P3 (or toward the point adjacent to the lower surface STPP_D of the step portion STPP) on the side surface STPP_S1 of the step portion STPP, but embodiments of the present disclosure are not limited thereto.

A side surface of the second taper forming angle adjusting electrode TE2 may form a second angle Φ2 with the plane STPP_P including the lower surface STPP_D of the step portion STPP. The side surface of the second taper forming angle adjusting electrode TE2 may form a fourth angle Φ2′ with an upper surface of the second taper forming angle adjusting electrode TE2. In one or more embodiments, the first angle Φ1 and the second angle Φ2 may be acute angles. The third angle Φ1′ and the fourth angle Φ2′ may be obtuse angles. The second angle Φ2 may be smaller than the first angle Φ1. In this regard, the fourth angle Φ2′ may be greater than the third angle Φ1′. In one or more embodiments, the first angle Φ1 may be 60° or less. The second angle Φ2 may be 40° or less.

When the second angle Φ2 is formed smaller than the first angle Φ1, the fourth angle Φ2′ may be formed greater than the third angle Φ1′. Because the fourth angle Φ2′ is defined by the upper surface of the second taper forming angle adjusting electrode TE2 and the side surface of the second taper forming angle adjusting electrode, a disconnection probability of the first electrode AND arranged on the upper surface and the side surface of the second taper forming angle adjusting electrode TE2 may be reduced due to the fourth angle Φ2′ formed relatively great/large. Accordingly, light emitting efficiency of the display device including the step portion STPP may increase.

An opening may be defined from (e.g., by) the upper surface STPP_U of the step portion STPP, a first side surface AE_S1 of the auxiliary electrode, and a second side surface AE_S2 of the auxiliary electrode. The first side surface AE_S1 of the auxiliary electrode may be opposite to (e.g., face) the side surface of the second taper forming angle adjusting electrode TE2. The side surface of the second taper forming angle adjusting electrode TE2 may form the fourth angle Φ2′ with the upper surface of the second taper forming angle adjusting electrode TE2, and the first side surface AE_S1 of the auxiliary electrode may be opposite to (e.g., face) the side surface of the second taper forming angle adjusting electrode TE2.

The first electrode AND may be arranged in the opening. The first electrode AND may cover the side surfaces of the second taper forming angle adjusting electrode TE2, the upper surface of the second taper forming angle adjusting electrode TE2, and the opening. As a contact area between the first electrode AND and the second taper forming angle adjusting electrode TE2 increases, supply efficiency of carriers increases, such that the light emitting efficiency of the display device may increase. Even though the first electrode AND and the second taper forming angle adjusting electrode TE2 are made of the same material, the second taper forming angle adjusting electrode TE2 should be formed to have a different thickness from the first electrode AND, and may thus be manufactured to be separated from the first electrode AND in a manufacturing process. An upper surface AND_U of the first electrode AND may be defined from the first electrode AND.

A first area AR1 and second areas AR2 may be defined on the upper surface STPP_U of the step portion STPP.

In cross section, one second area AR2 may be adjacent to one side of the first area AR1. The second area AR2 and the first area AR1 may be in contact with each other. In cross section, the other second area AR2 may be adjacent to the other side of the first area AR1. In cross section, a plurality of second areas AR2 may be formed. In this regard, the first area AR1 may be arranged between the plurality of second areas AR2 (e.g., be sandwiched or encapsulated by the plurality of second areas AR2).

The first area AR1 may be surrounded by the second areas AR2. For example, the second areas AR2 may be arranged around the first area AR1. A distance from the upper surface STPP_U of the step portion STPP to the upper surface of the first electrode AND in the first area AR1 may be different from that in the second area AR2.

The opening may be formed in the first area AR1. The second taper forming angle adjusting electrode TE2 (or the auxiliary electrode) may be arranged between the step portion STPP and the first electrode AND in the second area AR2. In the first area AR1, a distance A4 between the upper surface STPP_U of the step portion STPP and the upper surface AND_U of the first electrode AND may be defined. In the second area AR2, a distance A5 between the upper surface STPP_U of the step portion STPP and the upper surface AND_U of the first electrode AND may be defined. A distance A6 between the upper surface STPP_U of the step portion STPP and the upper surface of the second taper forming angle adjusting electrode TE2 may be defined.

In one or more embodiments, the distance A4 between the upper surface STPP_U of the step portion STPP and the upper surface AND_U of the first electrode AND in the first area AR1 may be about 10 nm or less. In one or more embodiments, the distance A4 may be about 8 nm or less. In one or more embodiments, the distance A4 may be about 6 nm or less. The distance A6 between the upper surface STPP_U of the step portion STPP and the upper surface of the second taper forming angle adjusting electrode TE2 may be about 30 nm or less.

A difference between the distance A6 between the upper surface STPP_U of the step portion STPP and the upper surface of the second taper forming angle adjusting electrode TE2 and the distance A5 between the upper surface STPP_U of the step portion STPP and the upper surface AND_U of the first electrode AND in the second area AR2 is a thickness of the first electrode AND, and may be substantially the same as the distance A4 between the upper surface STPP_U of the step portion STPP and the upper surface AND_U of the first electrode AND in the first area AR1.

The distance A4 between the upper surface STPP_U of the step portion STPP and the upper surface AND_U of the first electrode AND in the first area AR1 may be smaller than the distance A5 between the upper surface STPP_U of the step portion STPP and the upper surface AND_U of the first electrode AND in the second area AR2.

The distance A4 between the upper surface STPP_U of the step portion STPP and the upper surface AND_U of the first electrode AND in the first area AR1 may be smaller than the distances A1, A2, and A3 from the side surface STPP_S1 of the step portion STPP to the side surface AND_S of the first electrode AND. The distance A5 between the upper surface STPP_U of the step portion STPP and the upper surface AND_U of the first electrode AND in the second area AR2 may be smaller than the distances A1, A2, and A3 from the side surface STPP_S1 of the step portion STPP to the side surface AND_S of the first electrode AND.

The light emitting stack including the first stack layer IL1 and the second stack layer IL2 may be in contact with the first electrode AND in at least a portion of the first area AR1.

A central area ARC and outer areas ARO may be defined on the plane STPP_P including the lower surface STPP_D of the step portion STPP. The central area ARC may be surrounded by the outer areas ARO. The central area ARC may be arranged between a plurality of outer areas ARO in cross section. A direction from the first point P1 toward the third point P3 on the side surface STPP_S1 of the step portion STPP, projected on the plane STTP_P, may be a direction from the center area ARC toward the outer area ARO.

In the outer area ARO, a distance A8 from the plane STPP_P including the lower surface STPP_D of the step portion STPP to the upper surface AND_U of the first electrode AND may be defined. In the outer area ARO, a distance A7 from the plane STPP_P including the lower surface STPP_D of the step portion STPP to the upper surface of the second taper forming angle adjusting electrode TE2 may be defined. In one or more embodiments, the distance A7 from the plane STPP_P including the lower surface STPP_D of the step portion STPP to the upper surface of the second taper forming angle adjusting electrode TE2 in the outer area ARO may be about 30 nm or less.

The distance A8 from the plane STPP_P including the lower surface STPP_D of the step portion STPP to the upper surface AND_U of the first electrode AND in the outer area ARO may be smaller than the distance A1 between the first point P1 and the side surface AND_S of the first electrode AND, the distance A2 between the second point P2 and the side surface AND_S of the first electrode AND, and the distance A3 between the third point P3 and the side surface AND_S of the first electrode AND.

Both the distance A7 from the plane STPP_P including the lower surface STPP_D of the step portion STPP to the upper surface of the second taper forming angle adjusting electrode TE2 in the outer area ARO and the distance A8 from the plane STPP_P including the lower surface STPP_D of the step portion STPP to the upper surface AND_U of the first electrode AND in the outer area ARO may be greater than the distance A4 between the upper surface STPP_U of the step portion STPP and the upper surface AND_U of the first electrode AND in the first area AR1.

The distance A5 between the upper surface STPP_U of the step portion STPP and the upper surface AND_U of the first electrode AND in the second area AR2 may be substantially the same as the distance A8 from the plane STPP_P including the lower surface STPP_D of the step portion STPP to the upper surface AND_U of the first electrode AND in the outer area ARO.

A distance A9 from the plane STPP_P including the lower surface STPP_D of the step portion STPP to the upper surface AND_U of the first electrode AND in the first area AR1 may be about 200 nm or less. A distance A10 from the upper surface AND_U of the first electrode AND to a lower surface of the second electrode CAT in the first area AR1 may be about 50 nm or less.

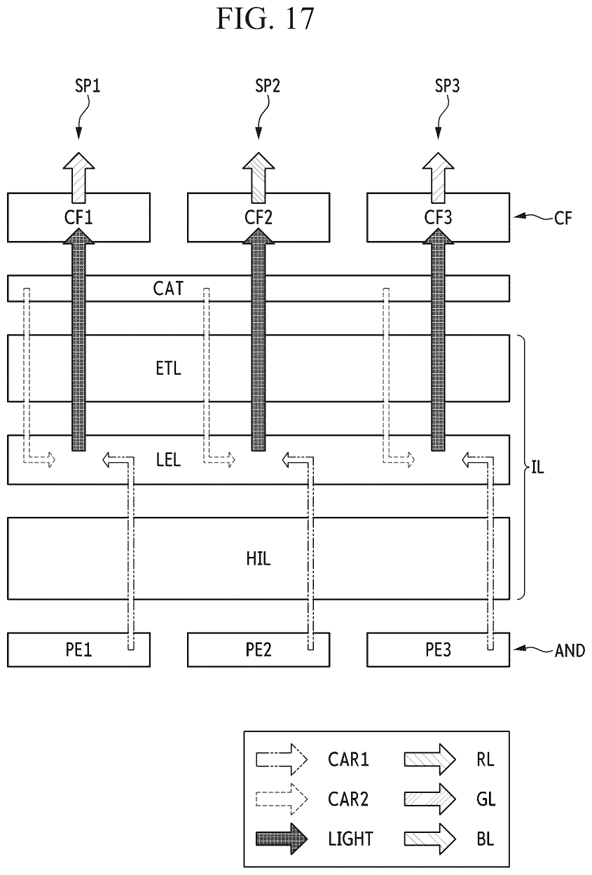

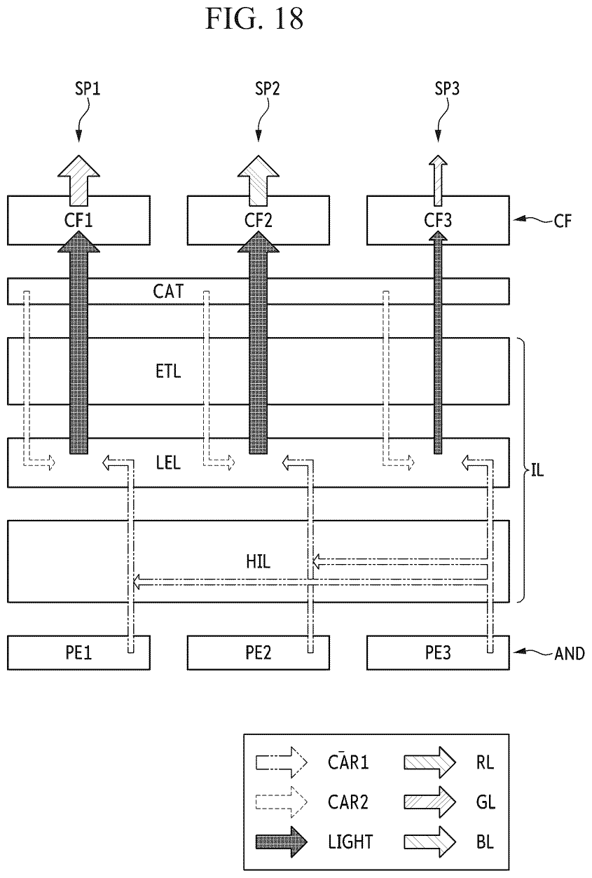

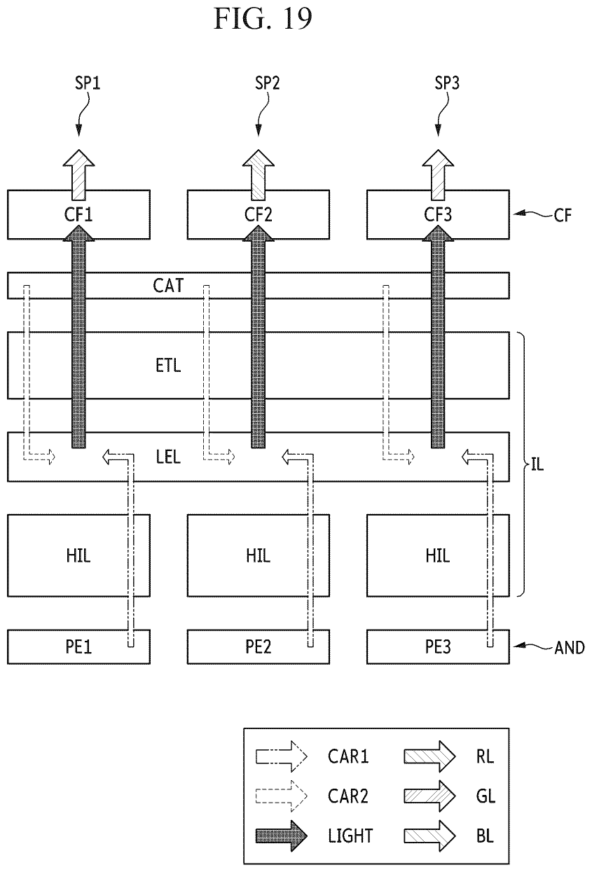

FIGS. 17 and 18 are each a schematic block diagram for describing a lateral leakage phenomenon. FIG. 19 is a schematic block diagram for describing a method for preventing or reducing the lateral leakage phenomenon according to one or more embodiments of the present disclosure.

Referring to FIG. 17, the first electrode AND may include a first pixel electrode PE1, a second pixel electrode PE2, and a third pixel electrode PE3. The first pixel electrode PE1 may correspond to the first anode electrode described above, the second pixel electrode PE2 may correspond to the second anode electrode described above, and the third pixel electrode PE3 may correspond to the third anode electrode described above.

First carriers CAR1 may be supplied from the first electrode AND to the sub-light emitting layer LEL included in the light emitting stack IL. Second carriers CAR2 may be supplied from the second electrode CAT to the sub-light emitting layer LEL included in the light emitting stack IL. In one or more embodiments, the first carrier CAR1 may be a positive charge (or a hole) and the second carrier CAR2 may be a negative charge (or an electron), but embodiments of the present disclosure are not limited thereto. The first carriers CAR1 and the second carriers CAR2 may combine with each other in the sub-light emitting layer LEL to form excitons. When the excitons are formed, light may be emitted from the sub-light emitting layer LEL.

As described above, light LIGHT having a white color may be emitted from the sub-light emitting layer LEL. The light LIGHT having the white color passes through the first color filter CF1 in the first sub-pixel SP1, such that a wavelength of the light LIGHT having the white color may be converted into a wavelength of first light RL having the wavelength band of the first color. The light LIGHT having the white color passes through the second color filter CF2 in the second sub-pixel SP2, such that a wavelength of the light LIGHT having the white color may be converted into a wavelength of second light GL having the wavelength band of the second color. The light LIGHT having the white color passes through the third color filter CF3 in the third sub-pixel SP3, such that a wavelength of the light LIGHT having the white color may be converted into a wavelength of third light BL having the wavelength band of the third color. Each of the first color, the second color, and the third color may be any one color selected from the group consisting of the red color, the green color, and the blue color so that these colors do not overlap each other.

Referring to FIG. 18, in a comparative embodiment, the first carriers CAR1 may reach the sub-light emitting layer LEL via the hole injecting layer or transporting layer HIL deposited in common in all of the first sub-pixel SP1, the second sub-pixel SP2, and the third sub-pixel SP3. However, the hole injecting layer or transporting layer HIL is deposited in common in the first sub-pixel SP1, the second sub-pixel SP2, and the third sub-pixel SP3, and thus, the first carriers CAR1 may move toward a direction corresponding to the second sub-pixel SP2 or the first sub-pixel SP1 via the hole injecting layer or transporting layer HIL. In this case, intensity of light emitted from the third sub-pixel SP3 may be relatively reduced, and intensity of light emitted from the first sub-pixel SP1 and the second sub-pixel SP2 may be relatively increased.

As described above, a case where light emitting efficiency intended by a practitioner is not implemented for each sub-pixel may occur due to the light emitting stack IL deposited in common. In such a case, it may be considered that a flow of carriers leaks to other sub-pixels, which is commonly referred to as a lateral leakage.

Referring to FIG. 19, if (e.g., when) the hole injecting layer or transporting layer HIL deposited in common is independently configured for each sub-pixel, the lateral leakage may be prevented or reduced. Accordingly, it is necessary to disconnect at least a portion of a component included in the light emitting stack IL for each of the plurality of sub-pixels.

In the display device according to one or more embodiments, the taper angle is adjusted by disposing the auxiliary electrode in order to prevent or reduce the disconnection of the first electrode AND. In contrast, in the display device according to one or more embodiments, the taper angle may also be adjusted in order to disconnect the light emitting stack IL.

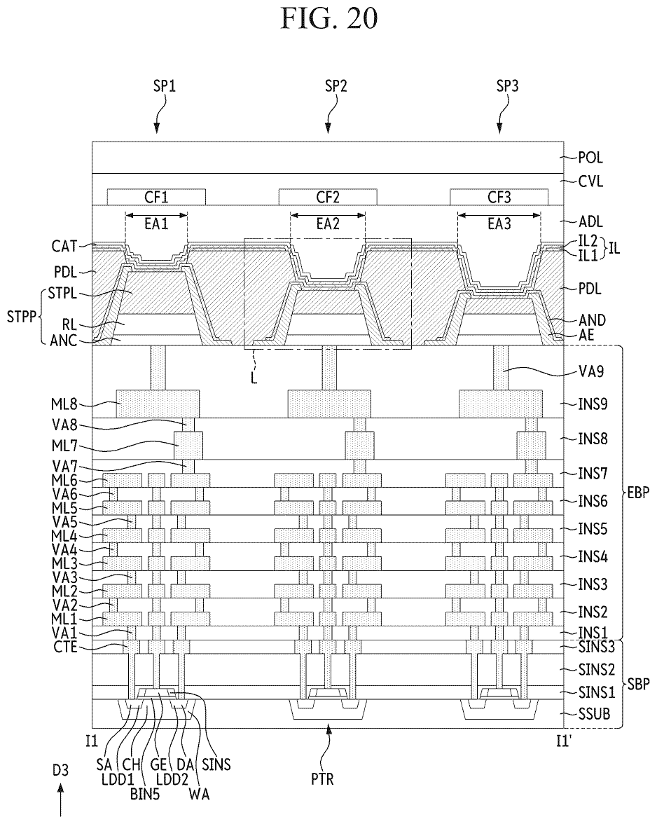

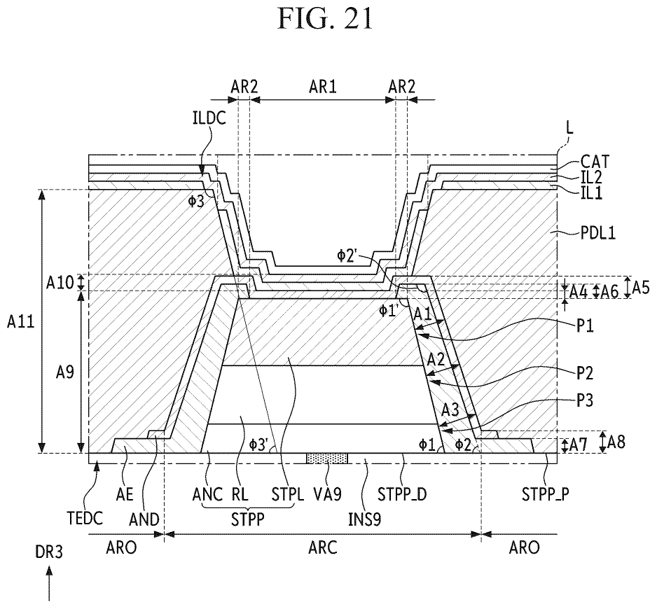

FIG. 20 is a cross-sectional view illustrating a display device according to a second embodiment of the present disclosure. FIG. 21 is a partially enlarged view illustrating the portion L of FIG. 20 according to one or more embodiments of the present disclosure. Components having substantially the same functions as those of the first embodiment described above (refer to FIG. 8, FIG. 13, and FIG. 16) are denoted by the same reference numerals, and an overlapping description thereof is not repeated for conciseness.

Referring to FIGS. 20 and 21, in one or more embodiments, the pixel defining film PDL may also be formed in a process of forming the step layer STPL. An upper surface of a first pixel defining film PDL1 (included in the pixel defining film PDL) may form a fifth angle Φ3 with a side surface of the first pixel defining film PDL1. The plane including the lower surface of the step portion STPP may form a sixth angle Φ3′ with the side surface of the first pixel defining film PDL1.

In one or more embodiments, the sum of the fifth angle Φ3 and the sixth angle Φ3′ may be a constant. If (e.g., when) the fifth angle Φ3 increases, the sixth angle Φ3′ may decrease, and if (e.g., when) the fifth angle Φ3 decreases, the sixth angle Φ3′ may increase. The fifth angle Φ3 may be an obtuse angle, and the sixth angle Φ3′ may be an acute angle.

In one or more embodiments, the fifth angle Φ3 may be relatively small, and the sixth angle Φ3′ may be relatively great or large. When the fifth angle Φ3 is formed relatively small, the sixth angle Φ3′ may be formed relatively great or large. Because the fifth angle Φ3 is the obtuse angle, if (e.g., when) the fifth angle Φ3 is formed relatively small, it may refer to that the sixth angle Φ3′ becomes relatively close to a right angle. Because the sixth angle Φ3′ is the acute angle, if (e.g., when) the sixth angle Φ3′ is formed relatively great or large, it may refer to that the sixth angle Φ3′ becomes relatively close to a right angle. In one or more embodiments, the sixth angle Φ3′ may be about 45° or more and about 60° or less.

A first stack layer IL1 may be arranged on the side surface and the upper surface of the first pixel defining film PDL1. When the fifth angle Φ3 is the obtuse angle and formed to be relatively close to the right angle (or formed to be relatively small), the first stack layer IL1 arranged on the upper surface of the first pixel defining film PDL1 and the first stack layer IL1 arranged on the side surface of the first pixel defining film PDL1 may be disconnected from each other. The hole injecting layer or transporting layers HIL included in the first stack layer IL1 may be disconnected from each other. Accordingly, the first stack layer IL1 may include light emitting stack disconnection portions ILDC. The emission area may be located between the light emitting stack disconnection portions ILDC. Accordingly, the lateral leakage of the display device may be reduced, and light emitting efficiency of each sub-pixel may not be reduced.

The first pixel defining film PDL1 may be made of a same material as the step layer STPL. For example, in one or more embodiments, both (e.g., simultaneously) the first pixel defining film PDL1 and the step layer STPL may be made of a silicon oxide (SiOₓ)-based inorganic material. A distance A11 from the plane STPP_P including the lower surface STPP_D of the step portion STPP to the upper surface of the first pixel defining film PDL1 may be defined. A thickness of the first pixel defining film PDL1 may be 30 nm or more.

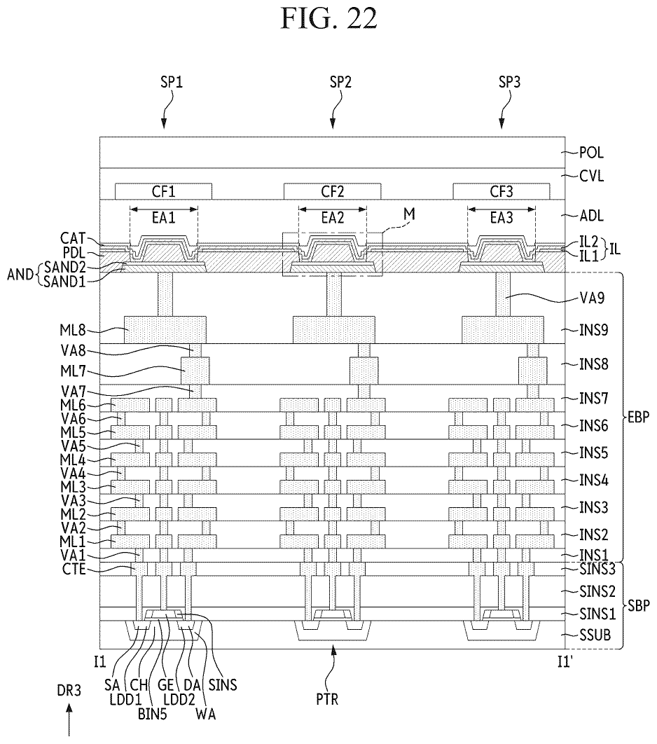

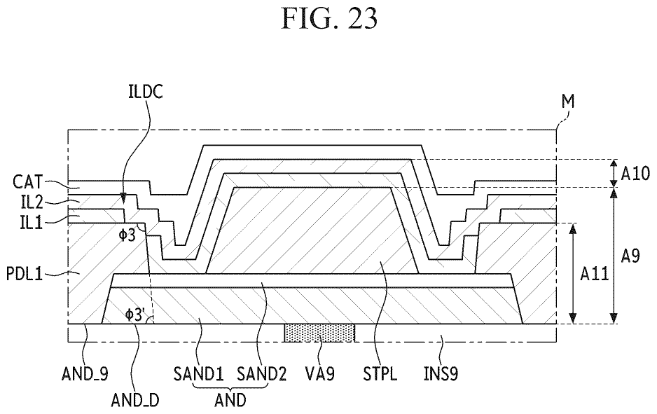

FIG. 22 is a cross-sectional view illustrating a modified example of FIG. 20 according to one or more embodiments of the present disclosure. FIG. 23 is a partially enlarged view illustrating the portion M of FIG. 22 according to one or more embodiments.

Referring to FIGS. 22 and 23, in one or more embodiments, the first electrode AND may include a first sub-electrode SAND1 and a second sub-electrode SAND2. The first sub-electrode SAND1 may be made of any one selected from among copper (Cu), aluminum (Al), tungsten (W), molybdenum (Mo), chromium (Cr), gold (Au), titanium (Ti), nickel (Ni), and neodymium (Nd), or an alloy thereof or a compound thereof. For example, in one or more embodiments, the first sub-electrode SAND1 is a reflective electrode, and may be made of aluminum (Al). The first sub-electrode SAND1 may correspond to the reflective electrode described above. The second sub-electrode SAND2 may be made of a transparent conductive material (TCO) such as ITO or IZO.

The step layer STPL may be arranged on the first electrode AND. The modified example may not include (e.g., may exclude) the above-described auxiliary electrode and/or the like, and only portions of the taper angles of the step layer STPL and the first pixel defining film PDL1 have been illustrated in the modified example. As shown in FIGS. 22 and 23, a fifth angle Φ3 may be formed between an upper surface of a first pixel defining film PDL1 (included in the pixel defining film PDL) with a side surface of the first pixel defining film PDL1, a sixth angle Φ3′ may be formed between a plane AND_9 including a lower surface AND_D of the first electrode AND with the side surface of the first pixel defining film PDL1, a distance A11 may be defined from the plane AND_9 including the lower surface AND_D of the first electrode AND to the upper surface of the first pixel defining film PDL1, a distance A9 may be defined from the plane AND_9 including the lower surface AND_D of the first electrode AND to an upper surface of the step layer STPL, and a distance A10 may be defined from the upper surface of the step layer STPL to an upper surface of the second stack layer IL2. Those components having substantially the same functions as those described above (refer to FIG. 8, FIG. 13, FIG. 16, FIG. 20, and FIG. 21) are denoted by the like reference numerals, and an overlapping description thereof is not repeated for conciseness.

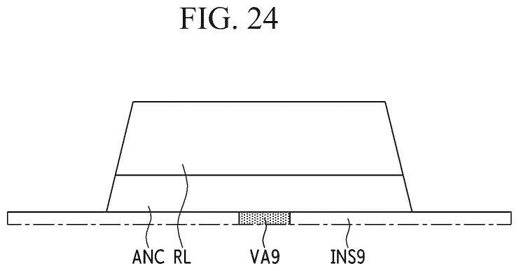

FIGS. 24 to 29 are cross-sectional views for describing a method of manufacturing a display device according to one or more embodiments of the present disclosure. A method of manufacturing the display device according to the first embodiment has been illustrated in FIGS. 24 to 29.

Referring to FIG. 24, the connection electrode ANC and the reflective electrode RL arranged on the connection electrode ANC may be formed.

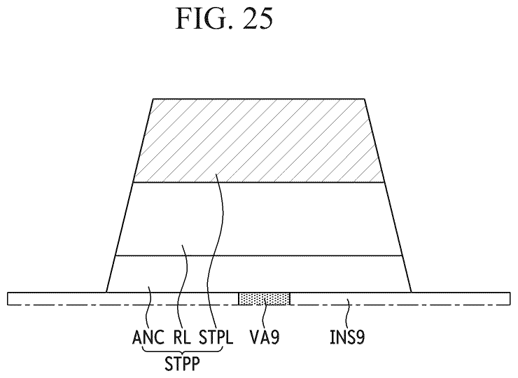

Referring to FIG. 25, the step layer STPL may be formed on the reflective electrode RL. The connection electrode ANC, the reflective electrode RL, and the step layer STPL may form the step portion STPP.

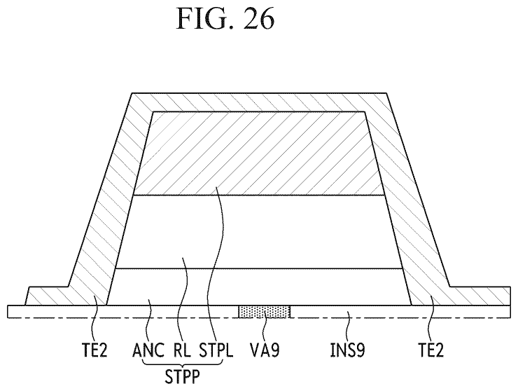

Referring to FIG. 26, the second taper forming angle adjusting electrode TE2 may be arranged on the plane including the lower surface of the step portion STPP, the upper surface of the step portion STPP, and the side surfaces of the step portion STPP. A thickness of the second taper forming angle adjusting electrode TE2 may not be constant.

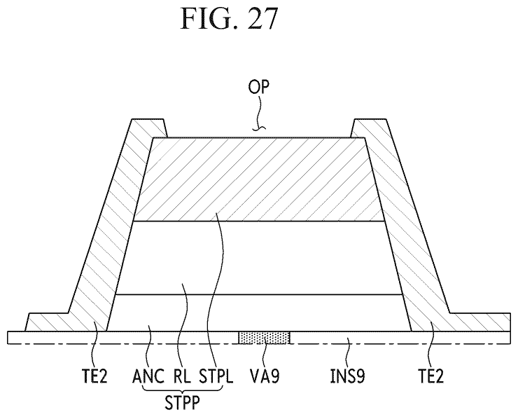

Referring to FIG. 27, an opening OP may be formed by removing at least a portion of an upper portion of the second taper forming angle adjusting electrode TE2.

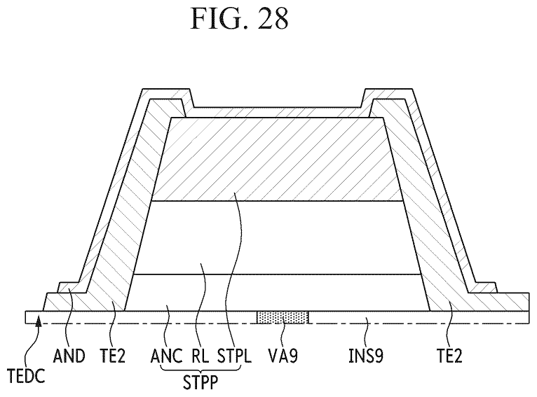

Referring to FIG. 28, the first electrode AND may be arranged on the opening OP, the side surfaces of the second taper forming angle adjusting electrode TE2, the upper surface of the second taper forming angle adjusting electrode TE2.

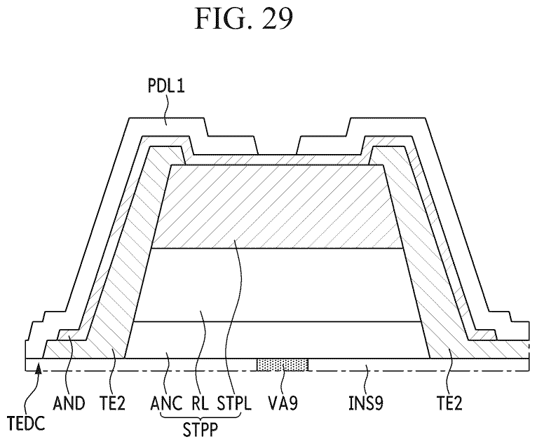

Referring to FIG. 29, the first pixel defining film PDL1 may be formed on the first electrode AND, and an opening may be formed in the first pixel defining film PDL1 in order to bring a light emitting stack to be arranged later and the first electrode AND into contact with each other.

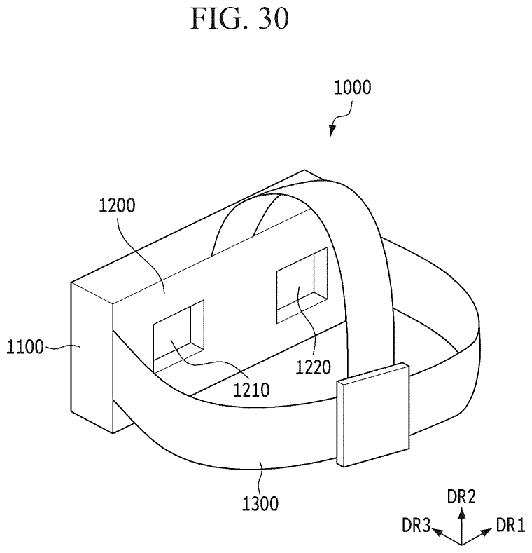

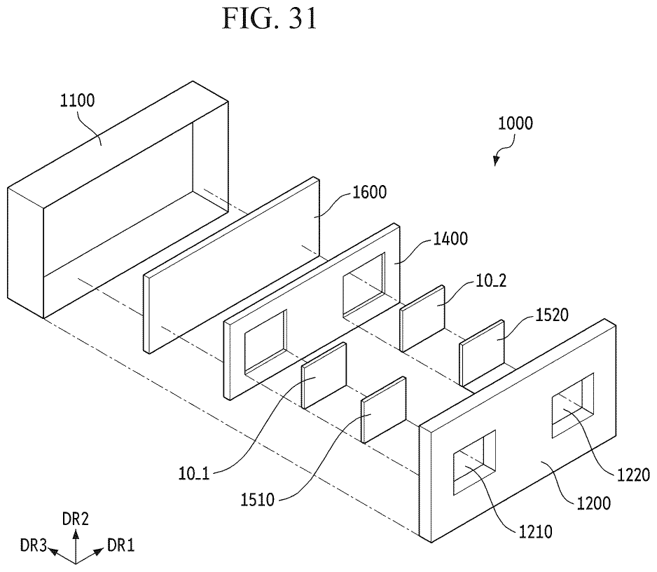

FIG. 30 is a perspective view illustrating a head mounted display according to one or more embodiments of the present disclosure. FIG. 31 is an exploded perspective view illustrating an example of the head mounted display device of FIG. 30 according to one or more embodiments.

Referring to FIG. 30 and FIG. 31, a head mounted display device 1000 according to one or more embodiments of the present disclosure includes a first display device 10_1, a second display device 10_2, a display device housing portion 1100, a housing portion cover 1200, a first eyepiece 1210, a second eyepiece 1220, a head mounted band 1300, a middle frame 1400, a first optical member 1510, a second optical member 1520, and a control circuit board 1600.

The first display device 10_1 provides an image to a user's left eye, and the second display device 10_2 provides an image to a user's right eye. Each of the first display device 10_1 and the second display device 10_2 is substantially the same as the display device 10 described with reference to FIGS. 1 to 8, and a description of the first display device 10_1 and the second display device 10_2 is thus not repeated.

The first optical member 1510 may be arranged between the first display device 10_1 and the first eyepiece 1210. The second optical member 1520 may be arranged between the second display device 10_2 and the second eyepiece 1220. Each of the first optical member 1510 and the second optical member 1520 may include at least one convex lens.

The middle frame 1400 may be arranged between the first display device 10_1 and the control circuit board 1600 and arranged between the second display device 10_2 and the control circuit board 1600. The middle frame 1400 serves to support and fix the first display device 10_1, the second display device 10_2, and the control circuit board 1600.

The control circuit board 1600 may be arranged between the middle frame 1400 and the display device housing portion 1100. The control circuit board 1600 may be connected to the first display device 10_1 and the second display device 10_2 through a connector. The control circuit board 1600 may convert an image source input from the outside into digital video data DATA, and transmit the digital video data DATA to the first display device 10_1 and the second display device 10_2 through the connector.

In one or more embodiments, the control circuit board 1600 may be to transmit digital video data DATA corresponding to a left eye image improved or optimized for the user's left eye to the first display device 10_1 and transmit digital video data DATA corresponding to a right eye image improved or optimized for the user's right eye to the second display device 10_2. In one or more embodiments, the control circuit board 1600 may be to transmit the same digital video data DATA to the first display device 10_1 and the second display device 10_2.

The display device housing portion 1100 serves to house the first display device 10_1, the second display device 10_2, the middle frame 1400, the first optical member 1510, the second optical member 1520, and the control circuit board 1600. The housing portion cover 1200 covers opened one surface of the display device housing portion 1100. The housing portion cover 1200 may include the first eyepiece 1210 at which the user's left eye looks and the second eyepiece 1220 at which the user's right eye looks. It has been illustrated in FIGS. 30 and 31 that the first eyepiece 1210 and the second eyepiece 1220 are separately arranged, but embodiments of the present disclosure are not limited thereto. The first eyepiece 1210 and the second eyepiece 1220 may be merged as one eyepiece.

The first eyepiece 1210 may be aligned with the first display device 10_1 and the first optical member 1510, and the second eyepiece 1220 may be aligned with the second display device 10_2 and the second optical member 1520. Accordingly, a user may view an image of the first display device 10_1 magnified as a virtual image by the first optical member 1510 through the first eyepiece 1210, and may view an image of the second display device 10_2 magnified as a virtual image by the second optical member 1520 through the second eyepiece 1220.

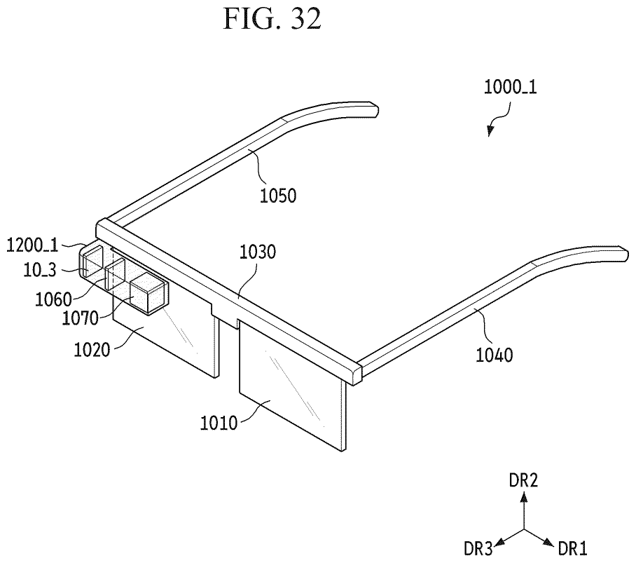

The head mounted band 1300 serves to fix the display device housing portion 1100 to a user's head so that the first eyepiece 1210 and the second eyepiece 1220 of the housing portion cover 1200 may be maintained in a state where they are arranged on the user's left eye and right eye, respectively. In one or more embodiments, when the display device housing portion 1200 is implemented to have a light weight and a small size, the head mounted display device 1000 may include an eyeglass frame as illustrated in FIG. 32 instead of the head mounted band 1300.

FIG. 32 is a perspective view illustrating a head mounted display according to one or more embodiments of the present disclosure.

Referring to FIG. 32, a head mounted display device 1000_1 according to one or more embodiments may be a glasses-type (kind) display device in which a display device housing portion 1200_1 is implemented to have a light weight and a small size. The head mounted display device 1000_1 according to one or more embodiments may include a display device 10_3, a left eye lens 1010, a right eye lens 1020, a support frame 1030, glasses frame legs 1040 and 1050, an optical member 1060, an optical path conversion member 1070, and the display device housing portion 1200_1.

The display device housing portion 1200_1 may include the display device 10_3, the optical member 1060, and the optical path conversion member 1070. An image displayed on the display device 10_3 may be magnified by the optical member 1060, converted in an optical path by the optical path conversion member 1070, and provided to a user's right eye through the right eye lens 1020. For this reason, a user may view an augmented reality image in which a virtual image displayed on the display device 10_3 through his/her right eye and a real image seen through the right eye lens 1020 are combined with each other.

It has been illustrated in FIG. 32 that the display device housing portion 1200_1 is arranged at a right end of the support frame 1030, but embodiments of the present disclosure are not limited thereto. For example, in one or more embodiments, the display device housing portion 1200_1 may be arranged at a left end of the support frame 1030, and in these embodiments, an image of the display device 10_3 may be provided to a user's left eye. In one or more embodiments, the display device housing portions 1200_1 may be arranged at both (e.g., simultaneously) the left and right ends of the support frame 1030, and in these embodiments, the user may view an image displayed on the display device 10_3 through both (e.g., simultaneously) his/her left and right eyes.

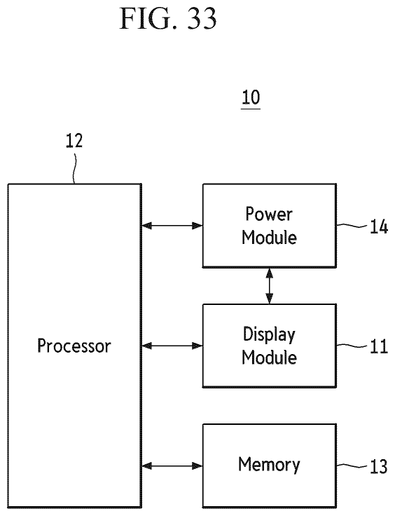

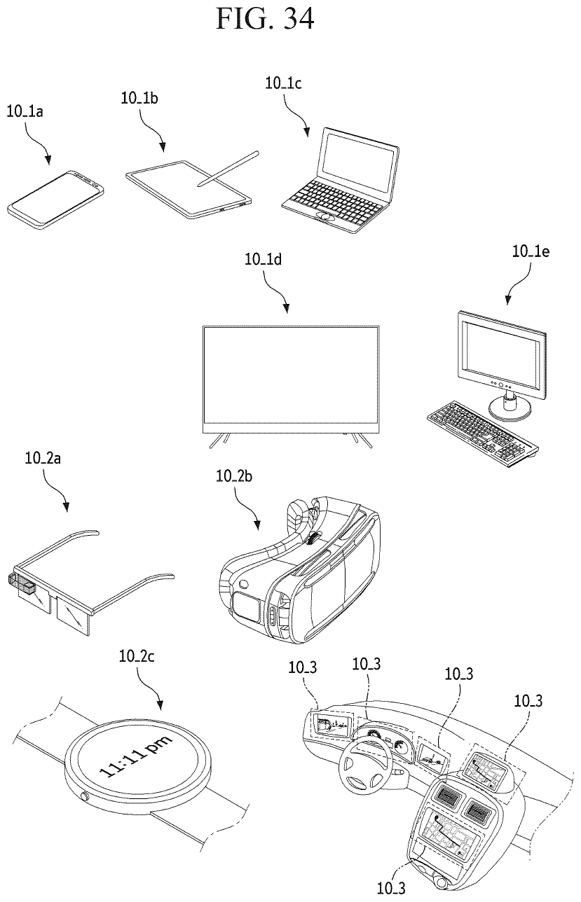

FIG. 33 is a block diagram of an electronic device according to one or more embodiments of the present disclosure. FIG. 34 is a schematic view illustrating electronic devices according to various embodiments of the present disclosure.

Referring to FIG. 33, an electronic device 10 according to one or more embodiments may include a display module 11, a processor 12, a memory 13, and a power module 14.

The processor 12 may include at least one of a central processing unit (CPU), an application processor (AP), a graphic processing unit (GPU), a communication processor (CP), an image signal processor (ISP), or a controller.

The memory 15 may store data information necessary for an operation of the processor 12 and/or the display module 11. When the processor 12 executes an application stored in the memory 15, an image data signal and/or an input control signal may be transmitted to the display module 11, and the display module 11 may process the received signal and output image information through a display screen.

The power module 14 may include a power supply module such as a power adapter or a battery device. The power module 14 may include a power conversion module. The power conversion module may convert power supplied by the power supply module to generate power necessary for an operation of the electronic device 10.

At least one of the respective components of the above-described electronic device 10 may be included in the display device according to one or more embodiments. In addition, some of individual modules functionally included in one module may be included in the display device, and the others of the individual modules may be provided separately from the display device. For example, the display device may include the display module 11, and the processor 12, the memory 13, and the power module 14 may be provided in the form of other devices within the electronic device 10 rather than the display device.

Referring to FIG. 34, one or more suitable electronic devices to which the display devices according to one or more embodiments of the present disclosure are applied may include image display electronic devices such as a smartphone 10_1a, a tablet PC 10_1b, a laptop computer 10_1c, a television (TV) 10_1d, and/or a monitor 10_1e for a desktop computer. Furthermore, the one or more suitable electronic devices to which the display devices according to one or more embodiments of the present disclosure are applied may include wearable electronic devices including one or more display modules, such as a smart glasses 10_2a, a head mounted display 10_2b, and/or a smart watch 10_2c, and/or vehicle electronic devices 10_3 including display modules, such as a center information display (CID) arranged on an instrument board, a center fascia, and/or a dashboard of a vehicle and/or a room mirror display. For example, various electronic devices may incorporate the display devices described in the present disclosure. These include, but are not limited to, smartphones, tablets, laptops, televisions, and monitors. Additionally, wearable devices—such as smart glasses, head-mounted displays, and smartwatches—as well as vehicle systems, including center information displays (CIDs) on dashboards and room mirror displays, may also utilize the disclosed display technology.

In the present disclosure, it will be understood that the terms “comprise(s)/comprising,” “include(s)/including,” or “have/has/having” specify the presence of stated features, integers, steps, operations, elements, and/or components, but do not preclude the presence or addition of one or more other features, integers, steps, operations, elements, components, and/or groups thereof. Additionally, the terms “comprise(s)/comprising,” “include(s)/including,” “have/has/having,” or other similar terms include or support the terms “consisting of” and “consisting essentially of,” indicating the presence of stated features, integers, steps, operations, elements, and/or components, without or essentially without the presence of other features, integers, steps, operations, elements, components, and/or groups thereof.

As utilized herein, the singular forms “a,” “an,” “one,” and “the” are intended to include the plural forms as well, unless the context clearly indicates otherwise. Further, the use of “may” when describing embodiments of the present disclosure refers to “one or more embodiments of the present disclosure”.

In the present disclosure, expressions such as “at least one of,” “one of,” and “selected from,” when preceding a list of elements, modify the entire list of elements and do not modify the individual elements of the list. For example, “at least one of a, b or c”, “at least one selected from a, b, and c”, “at least one selected from among a to c”, etc., may indicate only a, only b, only c, both (e.g., simultaneously) a and b, both (e.g., simultaneously) a and c, both (e.g., simultaneously) b and c, all of a, b, and c, or variations thereof.

In this disclosure, the phrase “on a plane,” or “in plan view,” refers to viewing a target portion from the top, and the phrase “on a cross-section” refers to viewing a cross-section formed by vertically cutting a target portion from a side.

In the context of the present application and unless otherwise defined, the terms “use,” “using,” and “used” may be considered synonymous with the terms “utilize,” “utilizing,” and “utilized,” respectively.

As utilized herein, the terms “substantially,” “about,” “approximately,” or similar terms are used as terms of approximation and not as terms of degree, and are intended to account for the inherent deviations in measured or calculated values that would be recognized by those of ordinary skill in the art. “About” or “approximately” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, ±20%, ±10%, or ±5% of the stated value. Also, it should be understood that, even if the terms “about,” “approximately,” or “substantially” are not expressly recited in a given element (e.g., a claim element), the scope of such element is intended to include variations that are insubstantial or within the understanding of one of ordinary skill in the art. For example, numerical values and ranges provided herein are intended to include tolerances and measurement uncertainties that would be recognized by those skilled in the art, and the elements (e.g., claim elements) should be construed accordingly to encompass such equivalents.

Any numerical range recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein and any minimum numerical limitation recited in the present disclosure is intended to include all higher numerical limitations subsumed therein. Accordingly, Applicant reserves the right to amend the disclosure, including the claims, to expressly recite any sub-range subsumed within the ranges expressly recited herein.

The light emitting element, the display module, the display panel, the display device, the electronic device/apparatus, the device-manufacturing apparatus, or any other relevant devices or components according to embodiments of the present disclosure described herein may be implemented utilizing any suitable hardware, firmware (e.g., an application-specific integrated circuit), software, or a combination of software, firmware, and hardware. For example, the various components of the device may be formed on one integrated circuit (IC) chip or on separate IC chips. Further, the various components of the device may be implemented on a flexible printed circuit film, a tape carrier package (TCP), a printed circuit board (PCB), or formed on one substrate. Further, the various components of the device may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random-access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the scope of the embodiments of the present disclosure.

A person of ordinary skill in the art would appreciate, in view of the present disclosure in its entirety, that each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner unless otherwise stated or implied.

Although example embodiments of the disclosure have been described above with reference to the accompanying drawings, it will be understood by those having ordinary skill in the technical field to which the disclosure belongs that the disclosure may be practiced in other specific forms without altering the technical idea or essential features of the disclosure. It should therefore be understood that the embodiments described above are example in all respects and are not intended to be limiting. It is to be understood that the scope of the present disclosure is defined by the appended claims and equivalents thereof rather than the detailed description described above, and all modifications and alterations derived from the claims and their equivalents fall within the scope of the present disclosure.

What is claimed is:

1. A display device, comprising:
a step portion defined by a plurality of side surfaces opposite to each other and a lower surface and an upper surface opposite to each other;
a first electrode on the upper surface and the plurality of side surfaces of the step portion;
a light emitting stack on the first electrode; and
a second electrode on the light emitting stack,
wherein a distance from a first point adjacent to the upper surface of the step portion on the side surface of the step portion to a side surface of the first electrode is different from a distance from a second point adjacent to the lower surface of the step portion on the side surface of the step portion to the side surface of the first electrode.

2. The display device of claim 1, wherein a distance from the upper surface of the step portion to an upper surface of the first electrode is smaller than a distance from the side surface of the step portion to the side surface of the first electrode.

3. The display device of claim 1, wherein a first area and a second area are defined on the upper surface of the step portion, and
on the upper surface of the step portion, a distance from the upper surface of the step portion to an upper surface of the first electrode is smaller in the first area than in the second area.

4. The display device of claim 3, wherein the light emitting stack is in contact with the first electrode in at least a portion of the first area.

5. The display device of claim 3, further comprising an auxiliary electrode between the step portion and the first electrode in the second area.

6. The display device of claim 5, wherein the auxiliary electrode comprises a same material as the first electrode.

7. The display device of claim 6, wherein the auxiliary electrode comprises an opening on the step portion, and
the first electrode is in the opening.

8. The display device of claim 7, wherein the opening is in the first area.

9. The display device of claim 1, wherein a plane comprising the lower surface of the step portion forms a first angle with the side surface of the step portion,
the plane comprising the lower surface of the step portion forms a second angle with the side surface of the first electrode, and
the first angle is greater than the second angle.

10. The display device of claim 9, wherein the first angle and the second angle are each an acute angle.

11. The display device of claim 1, wherein a central area and an outer area around the central area are defined on a plane comprising the lower surface of the step portion, and
a distance from the side surface of the step portion to the side surface of the first electrode increases from the central area toward a direction in which the outer area is located.

12. The display device of claim 11, wherein a distance from the plane comprising the lower surface of the step portion to an upper surface of the first electrode in the outer area is greater than a distance from the side surface of the step portion to the side surface of the first electrode.

13. The display device of claim 12, wherein a distance from the upper surface of the step portion to the upper surface of the first electrode is smaller than the distance from the plane comprising the lower surface of the step portion to the upper surface of the first electrode in the outer area.

14. The display device of claim 12, wherein a first area and a second area are defined on the upper surface of the step portion,
on the upper surface of the step portion, a distance from the upper surface of the step portion to the upper surface of the first electrode is smaller in the first area than in the second area, and
the distance from the upper surface of the step portion to the upper surface of the first electrode in the second area is substantially the same as the distance from the plane comprising the lower surface of the step portion to the upper surface of the first electrode in the outer area.

15. The display device of claim 1, wherein the step portion comprises a connection electrode, a reflective electrode on the connection electrode, and a step layer on the reflective electrode, and
the first electrode is electrically connected to the connection electrode on the side surface of the step portion.

16. An electronic device comprising:
a processor configured to provide an image signal;
a display module configured to receive an image signal provided from the processor and to display an image; and
a power module configured to supply power to the display module,
wherein the display module comprises:
a step portion defined by a plurality of side surfaces opposite to each other and a lower surface and an upper surface opposite to each other;
a first electrode on the upper surface and the plurality of side surfaces of the step portion;
a light emitting stack on the first electrode; and
a second electrode on the light emitting stack, and
wherein a distance from a first point adjacent to the upper surface of the step portion on the side surface of the step portion to a side surface of the first electrode is different from a distance from a second point adjacent to the lower surface of the step portion on the side surface of the step portion to the side surface of the first electrode.

17. The electronic device of claim 16, wherein a distance from the upper surface of the step portion to an upper surface of the first electrode is smaller than a distance from the side surface of the step portion to the side surface of the first electrode.

18. The electronic device of claim 16, wherein a first area and a second area are defined on the upper surface of the step portion, and
on the upper surface of the step portion, a distance from the upper surface of the step portion to an upper surface of the first electrode is smaller in the first area than in the second area, and
the display module further comprises a third electrode between the step portion and the first electrode in the second area.

19. The electronic device of claim 18, wherein the third electrode comprises a same material as the first electrode.

20. The electronic device of claim 16, wherein a plane comprising the lower surface of the step portion forms a first angle with the side surface of the step portion,
the plane comprising the lower surface of the step portion forms a second angle with the side surface of the first electrode, and
the first angle is greater than the second angle.
